(19) United States
(12) Patent Application Publication
(10) Pub. No.: US 2026/0088243 A1
(43) Pub. Date: Mar. 26, 2026

(54) ELECTRON SPECTROSCOPY APPARATUS AND METHODS

(71) Applicants: University of Surrey, Surrey (GB); VG Systems Limited, Cheshire (GB)

(72) Inventor: Mark Baker, Surrey (GB)

(21) Appl. No.: 19/108,717

(22) PCT Filed: Sep. 1, 2023
(86) PCT No.: PCT/EP2023/074062

§ 371 Date: Mar. 4, 2025

(30) Foreign Application Priority Data
Sep. 5, 2022 (GB) 2212932.4
Apr. 28, 2023 (GB) 2306322.5

(51) Int. Cl. H01J 37/073; H01J 37/285

(52) U.S. Cl. CPC H01J 37/073; H01J 37/285; H01J 2237/24485

(57) ABSTRACT

There is described a method of determining a chemical composition of a sample using electron spectroscopy, the method comprising: ablating material from an area on a surface of a sample by irradiating the area with one or more pulses of a laser; irradiating at least part of the area with an excitation beam of electrons or electromagnetic radiation; measuring intensities and energies of electrons emitted from the at least part of the area of the sample as a result of the excitation beam; and repeating the steps of: ablating material, irradiating with the excitation beam, and measuring intensities and energies, to determine a quantitative surface depth profile of the chemical composition of at least part of the sample. There is also described an electron spectroscopy apparatus for determining a chemical composition of a sample.

### TECHNICAL FIELD

The present invention relates to apparatus and methods for electron spectroscopy with depth profiling. In particular, the apparatus and methods provide improved composition accuracy, increased speed of depth profiling and greater depths probed.

### BACKGROUND

The surfaces and interfaces of materials represent boundaries between a solid and its environment or between two contacting surfaces. As such, surfaces and interfaces are sites of fundamentally important chemical, physical, electrical and mechanical processes enabling and affecting the operation and performance of structures, machines, devices and organisms.

In engineering applications, important physiochemical processes such as corrosion, oxidation, wear and adhesion occur at surfaces and interfaces. Understanding such phenomena, allows materials scientists and engineers to optimise their benefits and mitigate their detrimental effects. Such mitigation measures include surface engineering processes, such as the deposition of protective coatings or enhancing the mechanical properties of the surface through hardening or toughening processes. On the other hand, stronger adhesives have been developed through optimisation of their chemical formulation, enabling stronger bonds to be formed between the adhesive and material surface.

Surfaces and interfaces are crucial to the operation of functional devices. The performance of optoelectronic and electrochemical devices, sensors, actuators etc. are dependent on both the properties of bulk material and efficiency of surface/interface chemical and electrical processes. In order to achieve the desired multifunctional properties of the device, often multilayer structures of different materials are fabricated, where the thickness of the layers can vary from many microns to single atomic layers.

Accurate and reliable chemical analysis of a solid's bulk, surface and its interface with other solids is key to understanding the fabrication and properties of technologically important materials and devices, the development of new multifunctional materials and understanding material failures.

Two of the most widely used and highly developed surface chemical analysis methods are electron spectroscopic techniques, namely X-ray photoelectron spectroscopy (XPS) and Auger electron spectroscopy (AES). XPS is a photoemission spectroscopy method in which the electronic core level and valence band spectra from atoms in a solid are obtained by irradiating a material with a beam of X-rays. Chemical state information is extracted from the spectra in the form of electron binding energy shifts of the electrons due to variation in the local chemical environment. AES is similar to XPS but is based on analysis of an Auger electron emitted as part of the relaxation process following core level excitation. For AES, excitation occurs through the incident radiation being an X-ray or electron beam.

Both XPS and AES can provide quantification of surface chemical composition, with a sensitivity of 0.1-1 at. % for all elements except hydrogen and helium, to a depth of approximately 5 nm. Both methods also offer information on the chemical state of elements, but XPS is superior to AES in this respect for most elements.

Often, it is important to determine the chemical composition at depths greater than XPS/AES analysis depth. For example, examination of the chemical composition of a sub-micron multilayer optical filter or a 1-5 μm multi-process surface treatment for protective purposes. To achieve this, material from the surface has to be removed and the XPS/AES analysis repeated at the new surface revealed by the material removal. This cycle of material removal and XPS/AES analysis is continued until the chemical composition has been recorded for the depth of interest. The elemental composition at each level is calculated and plotted as a function of the number of cycles, known as a depth profile. If the depth is measured, with the assumption that the material removal rate is constant, a depth profile can be plotted in terms of chemical composition as a function of actual depth. For example, as shown in FIG. 1A, a thin film having a thickness of 50 to 500 nm, may be analysed using existing XPS depth profiling techniques. Thicker films having thicknesses up to around 5 μm may also be analysed, but this would take many hours to perform using conventional techniques.

In the XPS/AES depth profiling process, material removal is commonly achieved using ion beam bombardment with ion guns mounted in the spectrometers. The ion beam is aligned with the X-ray spot (for XPS) or the electron beam (for AES) on the surface of the sample, allowing the cyclic depth profiling process to be performed. The ion gun accelerates ions to a high energy that upon striking the surface have sufficient energy to remove surface atoms in a process known as sputtering. FIG. 1B is a schematic diagram of a conventional XPS apparatus with an ion beam. The apparatus comprises a vacuum chamber such as an UHV chamber 10 into which the sample 20 for analysis is inserted. An X-ray source 30 is provided which directs a beam of X-rays to a target area on the surface of the sample. The surface material emits electrons which are collected by the detector 50 and the electron energies measured by an electron analyser 40. The apparatus further comprises the ion gun 60. The ion gun may generate a beam of monatomic ions or (polyatomic) cluster ions which are directed at the sample surface to remove a layer from the surface by sputtering. Argon is commonly used to generate the ions but other sources of ions can be used.

AES and XPS commercial spectrometers were offered as scientific tools around 1970. Sputtering has been employed as the only practical method to generate XPS/AES depth profiles ever since. However, despite sputter depth profiling being employed for 50 years and it being the only current method to generate XPS/AES depth profiles, there are problems with sputter depth profiling, as described below:

### (i) Sample Damage and Preferential Sputtering

Many materials are ion beam sensitive. This means that the sputtering process damages the underlying surface, leading to a change in the chemical composition recorded by XPS/AES throughout the depth profile. In a chemical compound, this may take the form of sputtering one element more than other elements, known as preferential sputtering, and is particularly observed for inorganic materials. For polymeric materials, in addition to preferential sputtering of elements such as oxygen from the polymer, the ion beam damages the molecular structure. Hence, for ion beam sensitive materials, the capability of XPS/AES to provide accurate quantitative compositional information may be compromised and the incorrect chemical composition may be recorded throughout the XPS/AES sputter depth profile. Furthermore, the extent of preferential sputtering varies according to ion beam conditions and material composition. The degree of preferential sputtering cannot be reliably predicted for any new material or ion beam condition. Consequently, when depth profiling a potentially ion beam sensitive material, the analyst is unable to know whether preferential sputtering is changing the apparent composition of collected depth profile or not. The incorrect composition recorded during depth profile measurements and inability to know if this is occurring for the material under investigation are significant problems for a technique regarded as one able to provide accurate chemical compositions.

The argon cluster ion beams or gas cluster ion beams (GCIBs) mentioned above have enabled damage to most thermo-polymers to be substantially reduced during depth profiling. GCIBs have also been shown to reduce but not eradicate preferential sputtering in metal oxides. However, it has also led to new problems originating from the thermal spike associated with GCIB impact.

### (ii) Low Rate of Material Removal

Another problem with sputtering is the relatively low sputter rate for many materials, particularly inorganic materials. The sputter rate can be improved through the use of higher ion beam energies and currents, but increased energies generally introduce more surface damage. Using ion beam energies of 0.5 to 3 keV and typical currents delivered by ion guns used on modern XPS/AES instruments, sputter rates of tens to hundreds of nm per hour are achieved. For analysis where removal of more than 1-2 microns of material is required, taking into account the total time for both sputtering and analysis for thick layers that require significant material removal or multilayer structures that require a number of cycles of sputtering and measuring, XPS/AES depth profiling is usually performed overnight. XPS/AES depth profiling by ion beam induced sputtering to depths beyond approximately 5 microns is generally considered impractical. Hence, it is desirable to seek solutions to address the problems of performing XPS/AES depth profiling through thicker layers. For example, to analyse the bulk material, interlayers, or buried interfaces shown in FIG. 1A.

A paper by Graham et al., “Integrated experimental setup for angle resolved photoemission spectroscopy of transuranic materials”, Review of Scientific Instruments, 84, 093902, September 2013, describes work to develop angle resolved photoemission spectroscopy (ARPES) for transuranic materials. A technical report by Joyce et al., “Combining X-Ray Photoelectron Spectroscopy with Laser Ablation for Nuclear Forensics of Pu and U”, Report Number LA-UR-14-23989, from Los Alamos National Laboratory, describes methods of cleaning oxides from, and analysis of, Pu and U based materials.

### SUMMARY OF THE INVENTION

The present invention aims to solve problems related to: (a) incorrect chemical compositions of materials being determined and/or (b) limited rate of material removal during XPS/AES depth profiles. The present invention is particularly advantageous in being able to provide improved accuracy in the chemical composition and chemical state information during depth profiling for polymers, metal oxides, other inorganics, semiconductors, alloys and other materials. The ability to access increased depths for analysis compared to ion beam depth profiling allows access to sub-surface regions of varying chemical composition, buried interfaces and sub-surface discrete layers.

The invention is achieved through the use of laser pulses for material ablation in combination with electron spectroscopy techniques such as XPS and AES.

The present invention provides a method of determining a chemical composition of a sample using electron spectroscopy, the method comprising: ablating material from an area on a surface of a sample by irradiating the area with one or more pulses of a laser; irradiating at least part of the area with an excitation beam of electrons or electromagnetic radiation; measuring the intensities and energies of electrons emitted from the at least part of the area of the sample as a result of the excitation beam; and repeating the steps of: ablating material, irradiating with the excitation beam, and measuring the intensities and energies, to determine a quantitative surface depth profile, yielding the chemical composition of at least part of the sample. In preferred embodiments the method further comprises, prior to the first ablating of material from the area, irradiating at least part of an unablated area with an excitation beam of electrons or electromagnetic radiation and measuring intensities and energies of electrons emitted from the at least part of the unablated area of the sample as a result of the excitation beam.

The method may further comprise: determining, from the intensities and energies of the emitted electrons, the elemental composition of at least part of the ablated area and, optionally, determining the chemical state of the elements from the energies of the emitted electrons. The method may further comprise determining a depth or relative depth of the ablated area or areas, for example, in relation to the non-ablated surface adjacent to the ablated region or relative to the surface of the sample before ablation. For determining a depth or relative depth of the ablated area or areas, the method may further comprise determining an ablation rate per pulse for the material(s) present in the surface depth profile. Additionally, the method may further comprise conversion of the pulse number to the depth. Alternatively, the depth may be determined independently, for example through measuring the final crater depth with a profilometer type method, microscopy, white light interferometry or other methods.

The one or more pulses of a laser beam may be femtosecond pulses.

The method may further comprise repeating the step of ablating material, irradiating with the excitation beam, and measuring the intensity and energies of emitted electrons, to determine a depth profile down to a depth greater than 5 μm, greater than 10 μm, greater than 100 μm or greater than 200 μm, for example.

Each step of ablating material may comprise removing a layer from around one to many hundreds of nm or even from around one atomic layer such as 0.3 nm up to 10 μm (for example, from 0.3 nm to 1000 nm or from 1 nm to 10 μm, 1 nm to 1000 nm, or 10 nm to 500 nm).

The excitation beam may be a beam of X-rays and the spectroscopy may be XPS or AES. Alternatively, the excitation beam may be a beam of electrons and the spectroscopy may be AES.

The method may further comprise tilting the sample with respect to the ablation laser beam. Tilting the sample with respect to the laser beam may reduce crater bottom roughness and/or enable deeper depth profiles to be achieved. The method may comprise rotating or partially rotating the sample between ablation layers or steps (for example, by an extent that is less than 90°, such as between 15 and 85°, or between 25 and 75°, or between 35 and 75°, or between 45 and 65°, or between 5° and 60°, for example by 45, 55 or 65°). This again can reduce crater bottom roughness and/or enable deeper depth profiles and greater depth resolution of measurements to be achieved compared to simple laser ablation. The method may comprise incremental rotation of the sample surface between ablation layers or steps or laser pulses, or may comprise continuous rotation of the sample surface during the method. The sample surface rotation, which is rotational movement in the plane of the surface, has the effect to vary or randomise the laser direction with respect to the surface over multiple ablation steps. Otherwise, undesirable laser induced periodic surface structures (LIPSS) may build up if there are multiple laser pulses using the same direction on the surface. In this way, the sample surface rotation should preferably avoid rotation steps that are a multiple of 90 degrees, such as 90 or 180 degrees, and this is why a rotation of, for example, 55 degrees works well over many pulses. The laser beam may be a linearly polarised laser beam. The method may comprise incremental or continuous rotation of the angle of the linearly polarised laser beam during ablation or in between ablation steps. In other words, the orientation of the plane of polarisation of the laser beam may be rotated during ablation or in between ablation steps or laser pulses, for example incrementally or continuously. As with sample surface rotation, the rotation of the polarisation of the laser beam has the effect to vary or randomise the laser direction with respect to the surface over multiple ablation steps. Similarly, to avoid potential undesirable LIPSS, the laser polarisation rotation should preferably avoid rotation steps that are a multiple of 90 degrees, such as 90 or 180 degrees, and this is why a rotation of, for example, 55 degrees works well over many pulses. The method may comprise rotating the laser polarisation between ablation layers or steps by an extent that is less than 90°, such as between 15 and 85°, or between 25 and 75°, or between 35 and 75°, or between 45 and 65°, or between 5° and 60°, for example by 45, 55 or 65°. Alternatively, the method may comprise conversion of the linearly polarised beam into a beam with circular or elliptical polarisation. Use of a laser beam with circular or elliptical polarisation may optionally be used with rotation of the sample and/or polarisation. Embodiments of the method may therefore comprise (i) rotating the sample in a plane of the surface of the sample between the steps of ablating and/or between the laser pulses, and/or either (ii) rotating a plane of polarisation of the laser pulses between the steps of ablating and/or between the laser pulses, or (iii) converting a polarisation of the laser pulses into circular or elliptical polarisation. Sample rotation, polarisation rotation and/or polarisation conversion may reduce crater bottom roughness and/or enable deeper depth profiles to be achieved.

The one or more pulses may ablate material by a Coulombic explosion and/or thermal processes. The method may comprise adjusting one or more of pulse energy, pulse length and other parameters, and depending on material, to result in the most appropriate ablation process for analytical purposes.

The step of determining a chemical composition may comprise determining a concentration of the chemical elements. The concentration of the chemical elements may be stated as atomic percent (at. %) or a chemical stoichiometry, or in another way. The chemical concentration of the elements may be determined quantitatively from the relative measured intensities. The chemical elements and chemical state of the elements may be determined from the measured energies.

The step of ablating material may form a crater in the surface of the sample, and wherein at least part of the area irradiated with an excitation beam of X-rays/electrons may comprise an area at the bottom of the crater.

The crater preferably has a substantially flat bottom, and the excitation beam preferably irradiates at least part of the substantially flat bottom. The excitation beam preferably irradiates the at least part of the substantially flat bottom and preferably not the edges or sidewalls of the crater. A ratio of crater width (across the crater bottom) to the excitation beam spot size may be at least 3:1, or at least 4:1, or at least 5:1. A ratio of at least 5:1 is preferred.

The width of the substantially flat bottom of the crater may be greater than the width of the excitation beam. The width of the excitation beam may be determined to be the full width at half maximum (FWHM) of the beam intensity, a 1/e² diameter or other measure of beam width in which most of the energy of the beam is contained.

The step of ablating material from an area of the sample may comprise moving the relative position of the laser pulses to scan the pulses over the area on the surface of the sample to ablate the crater in the surface.

The relative position of the laser pulses may be moved by scanning the laser or by scanning the position of the sample. The scanning may comprise irradiating the sample with one or more pulses at a plurality of partially overlapping pixel positions.

The method may comprise passing the laser pulses through an optical set-up which converts the typically Gaussian intensity laser-pulse to have a substantially flat-top or top-hat intensity profile across its diameter incident at the sample surface. The laser pulses may produce a crater having a width corresponding to the width of the flat-top or top-hat intensity profile. The beam-shaping element may comprise a diffractive optical element. Alternatively, the beam-shaping element may be a refractive optical element or other optical element.

A combination of scanning and a flat-top or top-hat beam profile may also be used. The laser pulses each may have a duration less than 1 nanosecond (ns), less than 1 picosecond (ps), less than 500 femtoseconds (fs), less than 100 fs, less than 10 fs or less than 1 fs. As examples of ranges, the laser pulses may have durations in the range 1 fs to 1 ns, or 1 fs to 1 ps, or 1 fs to 500 fs, or 1 fs to 200 fs, or 1 fs to 100 fs. The lower limit of the range may be lower than 1 fs, such as 0.1 fs for example.

The laser pulse energy in one or more repetitions (pulses), preferably one pulse, should be sufficient to ablate material. In some embodiments, the energy per laser pulse may be in the range 10 nJ to 1000 μJ, or 1 μJ to 1000 μJ, or 10 μJ to 1000 μJ, such as between 50 and 500 μJ. Alternatively, the repetition may be a burst or train of pulses with the burst or train having these energies.

The diameter of the laser pulses at the sample surface may be in the range 1 to 1000 μm, such as 10 to 300 μm, or 50 to 150 μm.

The method may further comprise: setting or adjusting, by a controller, one or more parameters of the pulses of the laser based on composition information about the sample; and performing the step of ablating material, wherein the parameters of the laser pulses are set or adjusted by the controller. The controller may be a computing device having a memory and processor.

The one or more parameters of the laser pulses that may be set or adjusted by the controller comprise one or more of: pulse duration, pulse energy, repetition frequency, wavelength and spot size.

The step of setting or adjusting may further comprise: receiving an input from a user indicating the composition information about the sample; and the controller adjusting the one or more laser parameters based on the composition information.

The method may further comprise: performing a survey scan or survey profile to determine an approximate measure of elemental components in the sample; and generating the one or more parameters of the laser pulses based on the approximate measure.

The method may further comprise performing mechanical profilometry or microscopy (for example, atomic force microscopy) or white light interferometry (WLI) of the sample surface; and generating or adjusting the one or more parameters of the laser pulses based on the profilometry, microscopy or interferometry.

The controller may use a reference database or algorithm to determine the laser parameters based on the information about the sample.

The method may comprise, following steps of ablating material, irradiating with an excitation beam and measuring electron intensities and energies, adjusting the one or more parameters of the laser based on measured or predicted composition information about the sample at a depth following the ablation, and repeating the steps of ablating material, irradiating with an excitation beam and measuring electron intensities and energies using the adjusted one or more parameters of the laser.

The method may further comprise repeating the steps of adjusting, ablating material, irradiating with an excitation beam and measuring electron intensities and energies until the sample has been analysed to a target depth.

The method may comprise placing the sample on a sample stage in a vacuum chamber and following the steps of ablating material, irradiating with the excitation beam, and measuring intensities and energies of emitted electrons. The sample may not be moved by an amount greater than the laser spot or scan size between the step of ablating and the step of irradiating with an excitation beam.

The laser pulses and excitation beam may be spatially coincident at the sample surface. In this context, the term coincident does not mean that the laser pulses and excitation beam must have exactly the same spatial extent and position at the sample surface but rather that there is at least an overlap. Preferably, the excitation beam spot size is smaller than the laser pulse spot size. The excitation pulses may be centred on the laser pulses.

The step of ablating may comprise raster scanning the ablation laser pulses relative to the sample surface, and wherein the excitation beam is coincident with at least part of the ablated sample surface area.

The present invention provides further methods as we will now set out. These methods may be combined in any combinations.

A method of electron spectroscopy, comprising: ablating material from an area on a surface of a sample by irradiating the area of with one or more pulses of a laser, wherein the ablation forms a crater in the surface of the sample; irradiating at least part of the ablated area at the bottom of the crater with an excitation beam of electrons or electromagnetic radiation such as X-rays; measuring intensities and energies of electrons emitted from the at least part of the area of the sample as a result of the excitation beam; and determining a chemical composition of the surface of the crater based on the measured intensities and energies of the emitted electrons. The step of ablating may be repeated to form greater depth craters.

A method of electron spectroscopy, comprising: ablating material from an area on a surface of a sample by irradiating the area of the sample with one or more pulses of a laser, wherein the laser pulses have a duration less than 1 ns, less than 1 ps, less than 500 fs, less than 100 fs, less than 10 fs or less than 1 fs; irradiating at least part of the ablated area with an excitation beam of electrons or electromagnetic radiation such as X-rays. The method may further comprise: measuring intensities and energies of electrons emitted from at least part of the area of the sample as a result of the excitation beam; and determining a chemical composition of the surface based on the measured intensities and energies of the emitted electrons.

A method of electron spectroscopy, comprising: setting, by a controller, one or more parameters of pulses of a laser based on composition information about a sample; ablating material from an area on a surface of the sample by irradiating the area of the sample with one or more pulses of the laser, wherein the parameters of the pulses have been set by the controller; irradiating at least part of the area with an excitation beam of electrons or electromagnetic radiation such as X-rays; measuring intensities and energies of electrons emitted from the at least part of the area of the sample as a result of the excitation beam; and determining a chemical composition of the surface based on the measured intensities and energies of the emitted electrons.

A method of electron spectroscopy, comprising: placing a sample on sample stage in a vacuum chamber; ablating material from an area on a surface of the sample by irradiating the area of the sample with one or more pulses of a laser; irradiating at least part of the area with an excitation beam of electrons or electromagnetic radiation such as X-rays; measuring intensities and energies of electrons emitted from the at least part of the area of the sample as a result of the excitation beam; determining a chemical composition of the surface based on the measured intensities and energies of the emitted electrons; wherein the sample is not moved by an amount greater than the size of the laser spot or scanned area between the step of ablating and the step of irradiating with an excitation beam.

A method of electron spectroscopy, comprising: placing a sample on sample stage in a vacuum chamber; ablating material from an area on a surface of the sample by irradiating the area of the sample with one or more pulses of a laser, the laser configured to direct pulses at the sample surface; irradiating at least part of the area with an excitation beam of electrons or electromagnetic radiation such as X-rays; measuring intensities and energies of electrons emitted from the at least part of the area of the sample as a result of the excitation beam; determining a chemical composition of the surface based on the measured intensities and energies of the emitted electrons; wherein the laser pulses and excitation beam are spatially coincident at the sample surface.

The present invention provides an electron spectroscopy apparatus for determining a chemical composition of a sample, the apparatus comprising: a vacuum chamber; a sample stage mounted in the vacuum chamber, the sample stage configured for receiving a sample to be analysed; a laser configured to generate and direct laser pulses at a target area of the sample to ablate a surface of the sample; an excitation beam source configured to generate and direct an excitation beam of electrons or electromagnetic radiation at the target area of the sample; and an electron detector and analyser configured to measure the intensities and energies of electrons emitted from the sample surface in response to the excitation beam and to determine a quantitative surface depth profile of the chemical composition of the sample.

The electron analyser and detector may be further configured to determine, from the intensities and energies of the emitted electrons, the elemental composition of the target area and, optionally, to determine the chemical state of the elements in the elemental composition from the intensities and energies of the emitted electrons. The electron analyser may comprise an electrostatic toroidal capacitor type analyser, for example an electrostatic concentric hemispherical analyser. Other types of electron analyser, such as a cylindrical mirror analyser, may be used. The electrons may be detected using one or more electron multipliers. The electron multiplier(s) may comprise a single channeltron, or arrays of channeltrons, or microchannel plates. The detector, also known as an electron counter, may comprise one or more Channel Electron Multiplier (Channeltron) detectors. Alternatively, channelplate multipliers used in conjunction with a position sensitive element such as Delay Line Detector (DLD) or a Resistive Anode Divider can be used for simultaneous detection of the number of electrons and landing position of each electron

The laser is preferably configured to generate nanosecond, or picosecond, or more preferably femtosecond, pulses.

The excitation beam source may be configured to generate a beam of X-rays or a beam of electrons.

The excitation beam source may be configured to generate a beam of X-rays and the electron detector and analyser are configured to measure photoelectrons and Auger electrons. Alternatively, the excitation beam source is configured to generate a beam of electrons and the electron analyser is configured to measure Auger electrons. If the excitation beam is a beam of X-rays, the electrons are photoelectrons and the spectroscopy is XPS. If the excitation beam is an electron beam, the electrons are Auger electrons and spectroscopy is AES.

The sample stage may be configured to be tilted with respect to the ablation laser beam.

The sample stage may comprise positioning devices to move the sample in orthogonal directions in the plane of the sample, for example, so as to raster scan the sample with respect to the position of incidence of the ablation laser pulses.

The laser may comprise a mirror to adjust the position of incidence of the laser pulses on the sample so to raster scan the laser pulses across the sample.

The laser may comprise a beam-shaping element to convert the laser-pulses to have a substantially flat-top or top-hat intensity profile across its diameter incident at the sample surface.

The laser the beam-shaping element may be configured to convert the laser-pulses to have the substantially flat-top or top-hat intensity profile across its diameter incident at the sample surface. The diameter at the surface of the sample is preferably greater than the diameter of the excitation beam at the surface of the sample.

The beam-shaping element may comprise a diffractive optical element, a refractive optical element or other optical element.

The laser may be configured to generate pulses each having a duration less than 1 ns, less than 1 ps, less than 500 fs, less than 100 fs, less than 10 fs or less than 1 fs.

The laser is configured to generate pulses having an energy per in the range 10 nJ to 1000 μJ or 1 to 1000 μJ, or 10 μJ to 1000 μJ, such as between 50 and 500 μJ.

The laser may be configured to generate pulses having a spot size at the sample surface in the range 1 to 1000 μm, such as 10 to 300 μm, or 50 to 150 μm.

The controller may be configured to adjust one or more parameters of the pulses of the laser based on composition information about a sample.

The one or more parameters of the laser pulses set by the controller may comprise one or more of: pulse duration, pulse energy, repetition frequency, wavelength and spot size.

The controller may be configured to: receive an input from a user indicating the composition information about the sample; and adjust the one or more laser parameters based on the composition information.

The controller may be configured to refer to a reference database or algorithm to determine the laser parameters based on the information about the sample.

The laser and excitation beam source may be respectively configured to direct the laser pulses and excitation beam to be spatially coincident at the sample surface.

The present invention provides further apparatus as we will now set out. These apparatus may be combined in any combinations.

An electron spectroscopy apparatus, comprising: a vacuum chamber; a sample stage mounted in the vacuum chamber, the sample stage configured for receiving a sample to be analysed; a laser configured to generate and direct laser pulses at a target area of the sample to ablate a surface of the sample, wherein the laser is configured to ablate material to form a crater in the surface of the sample; an excitation beam source configured to generate and direct an excitation beam of electrons or electromagnetic radiation at the target area of the sample; and an electron analyser and detector configured to measure energies and intensities of electrons emitted from the sample surface in response to the excitation beam and to determine a surface depth profile of the chemical composition of the sample.

An electron spectroscopy apparatus, comprising: a vacuum chamber; a sample stage mounted in the vacuum chamber, the sample stage configured for receiving a sample to be analysed; a laser configured to generate and direct laser pulses at a target area of the sample to ablate a surface of the sample, wherein the laser is configured to generate pulses having a duration less than 1 ns, less than 1 ps, less than 500 fs, less than 100 fs, less than 10 fs or less than 1 fs; an excitation beam source configured to generate and direct an excitation beam of electrons or electromagnetic radiation at the target area of the sample; and an electron analyser and detector configured to measure energies and intensities of electrons emitted from the sample surface in response to the excitation beam and to determine a surface depth profile of the chemical composition of the sample.

An electron spectroscopy apparatus, comprising: a vacuum chamber; a sample stage mounted in the vacuum chamber, the sample stage configured for receiving a sample to be analysed; a laser configured to generate and direct laser pulses at a target area of the sample to ablate a surface of the sample; a controller configured to adjust or set one or more parameters of pulses of the laser based on information about the sample; an excitation beam source configured to generate and direct an excitation beam of electrons or electromagnetic radiation at the target area of the sample; and an electron analyser and detector configured to measure energies and intensities of electrons emitted from the sample surface in response to the excitation beam and to determine a surface depth profile of the chemical composition of the sample.

An electron spectroscopy apparatus, comprising: a vacuum chamber; a sample stage mounted in the vacuum chamber, the sample stage configured for receiving a sample to be analysed; a laser configured to generate and direct laser pulses at a target area of the sample to ablate a surface of the sample; an excitation beam source configured to generate and direct an excitation beam of electrons or electromagnetic radiation at the target area of the sample; and an electron analyser and detector configured to measure energies and intensities of electrons emitted from the sample surface in response to the excitation beam and to determine a surface depth profile of the chemical composition of the sample, wherein the sample stage is configured for a maximum amount of movement corresponding the to the size of the sample.

An electron spectroscopy apparatus, comprising: a vacuum chamber; a sample stage mounted in the vacuum chamber, the sample stage configured for receiving a sample to be analysed; a laser configured to generate and direct laser pulses at a target area of the sample to ablate a surface of the sample; an excitation beam source configured to generate and direct an excitation beam of electrons or electromagnetic radiation at the target area of the sample; and an electron analyser and detector configured to measure energies and intensities of electrons emitted from the sample surface in response to the excitation beam and to determine a surface depth profile of the chemical composition of the sample, wherein the laser and excitation beam source are respectively configured to direct the laser pulses and excitation beam to be spatially coincident at the sample surface.

In each of the above methods and apparatus, the excitation beam may be a beam of electrons or a beam of electromagnetic radiation, such as X-rays.

### BRIEF DESCRIPTION OF THE DRAWINGS

Embodiments of the present invention, and aspects of the prior art, will now be described with reference to the accompanying drawings, of which:

FIG. 1A is a schematic diagram showing analysis depth that can be achieved using conventional XPS;

FIG. 1B is a schematic diagram of an XPS apparatus with ion source for sputter removal of material layers;

FIG. 2 is a schematic diagram of an XPS apparatus with ablation laser according to the present invention;

FIG. 3A is a schematic diagram of an optical setup for an ablation laser according to the present invention;

FIG. 3B is a schematic diagram showing sample surface rotation and/or laser polarisation rotation or conversion during ablation steps;

FIG. 4A is a process flow chart of steps for performing a method of electron spectroscopy using laser ablation to generate a composition depth profile;

FIG. 4B shows different depth resolutions obtained when depth profiling through a nickel/chromium multilayer structure with (left hand graph) and without (right hand graph) rotation of the laser polarization between pulses;

FIGS. 5A and 5B are XPS spectra respectively showing the background signal for a Ag 3d XPS spectrum and a peak fit of a C 1s XPS spectrum showing the individual peaks for carbon in different chemical states;

FIGS. 6a and 6b respectively show an example of a quantified laser ablation XPS depth profile, plotted as a function of ablation level and depth;

FIG. 7a is a schematic diagram of a beam scanning approach to laser ablation, and FIG. 7b is a schematic cross-section view through the ablated area with excitation beam incident thereon;

FIG. 8 is a schematic representation of Gaussian beam overlap able to achieve uniform intensity across pixels for ablation;

FIG. 9 is a schematic representation of an optical set-up to generate a top-hat or flat-top beam intensity profile;

FIG. 10 are plots of a top-hat intensity profile of a laser pulse showing the intensity in plan and cross-section views;

FIG. 11 is graph showing a mechanical profilometry trace over a crater in a sample surface formed by raster scanning pulses according to FIG. 10;

FIGS. 12a-12c are chemical composition depth profiles of a TiO₂ sample obtained using laser ablation, conventional sputtering and cluster ion beam sputtering, and FIGS. 12d-12f are corresponding photoelectron spectroscopy spectra;

FIGS. 13a and 13b are surface depth profiles of InP respectively obtained using laser ablation and sputtering;

FIGS. 14a-c relate to a surface depth profile of iron oxide layers on iron obtained using laser ablation, with FIG. 14a showing XPS spectra from the three different layered regions (Fe^{2+/3+}, Fe²⁺ and Fe⁰) in the surface profiles of FIGS. 14b and 14c; and

FIG. 15a is a surface depth profile of PET on steel obtained using laser ablation with FIGS. 15b and 15c showing corresponding XPS spectra from the PET layer.

### DETAILED DESCRIPTION

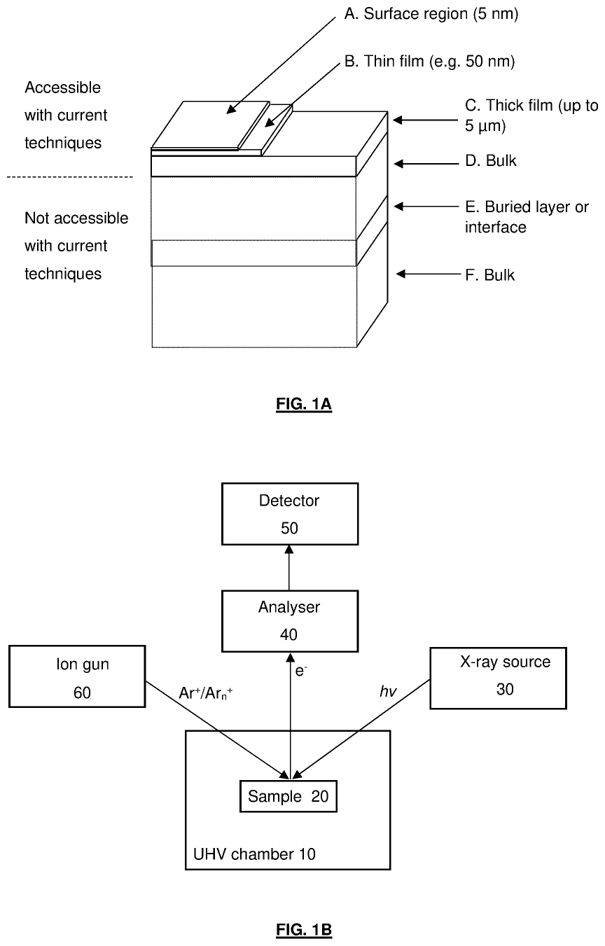

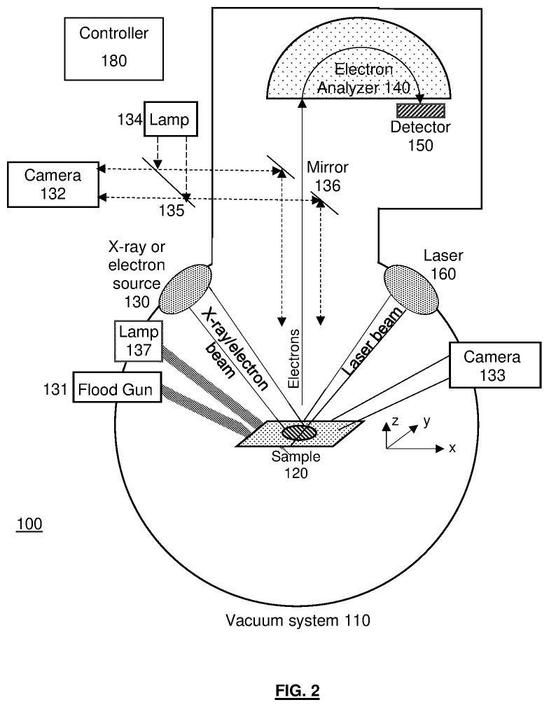

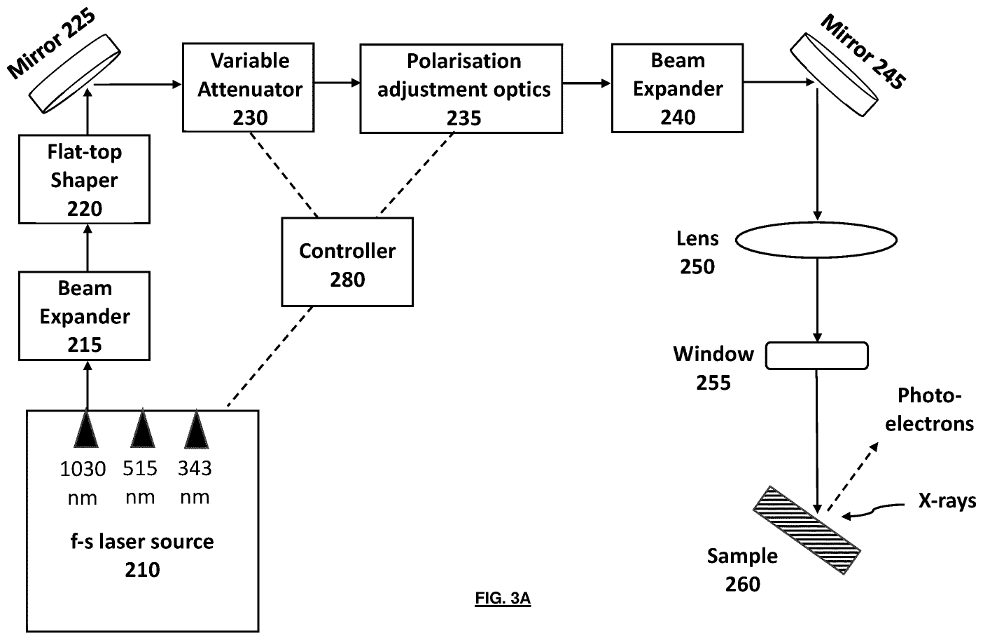

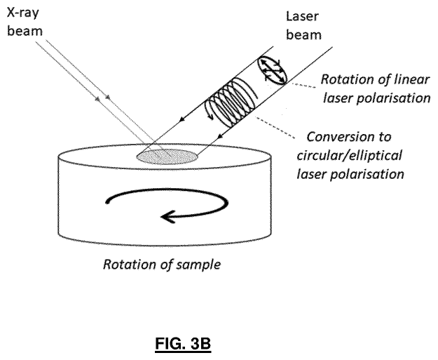

FIG. 2 is a schematic diagram of an X-ray photoelectron spectroscopy (XPS) apparatus 100 according to an embodiment of the present invention. The apparatus comprises a vacuum chamber 110, which may be an UHV vacuum chamber similar to the vacuum chamber 10 shown in FIG. 1B. The apparatus further comprises a sample stage on to which sample 120 may be received. An X-ray source 130 is provided for generating an excitation beam of X-rays. Alternatively, for Auger electron spectroscopy (AES) an electron source may be provided for generating an excitation beam of electrons. An electron analyser 140 is provided for analysing photoelectrons and Auger electrons generated by the incidence of the excitation beam on the sample surface before they are detected by the detector 150. A laser 160, such as a femtosecond laser, is provided for irradiating the sample surface to ablate the sample surface such that XPS or AES can be performed at a depth. The laser replaces the argon ion gun or etching source 60 shown in FIG. 1B. The apparatus may further comprise a controller 180, for example, for controlling parameters of the laser. As shown in FIG. 2 the sample stage receives the sample 120 in the vacuum chamber 110. The sample stage 120 may be a movable sample stage comprising positioning mechanisms to adjust the position of the sample in two orthogonal directions in the sample plane such as x and y directions. The positioning mechanism may also have z direction (height) adjustment. The sample stage may also comprise a positioning mechanism for in-plane rotational movement such as rotation in the x-y plane. This in-plane rotational movement is further shown in FIG. 3B. The sample stage may also comprise a tilt mechanism for tilting the sample with respect to the ablation laser beam.

The electron analyser 140 may comprise an electrostatic toroidal capacitor type analyser, for example an electrostatic concentric hemispherical analyser. Other types of electron analyser, such as a cylindrical mirror analyser, may be used. The electron analyser measures energies of the emitted electrons.

The detector 150, also known as an electron counter, may comprise one or more Channel Electron Multiplier (Channeltron) detectors. Alternatively, channelplate multipliers used in conjunction with a position sensitive element such as Delay Line Detector (DLD) or a Resistive Anode Divider can be used for simultaneous detection of the number of electrons and landing position of each electron. The detector measures the intensities of the emitted electrons.

The X-ray or electron source 130 is configured to generate and direct electrons or X-rays to the sample surface. The X-rays may be monochromatic X-rays and may be generated from a high-energy electron gun arranged to accelerate electrons towards a target anode. The target anode may be aluminium such that the resulting X-rays are generated at an appropriate energy. The X-rays may be directed to the chamber via a monochromator crystal and focused towards the sample surface. The X-rays pass through an opening or aperture to pass to the sample surface. On incidence at the sample surface the X-rays cause the emission of photoelectrons or Auger electrons.

The apparatus may further comprise a flood gun 131 to provide charge neutralization at the sample surface during analysis because the emission of electrons can cause a positive charge to build up on the sample. This is most acute where the sample surface is insulating because the charge build up remains at the surface and is not dissipated by charge transport through the sample. The positive charge can affect the XPS spectrum by causing peaks to shift to higher binding energies and become distorted. The flood gun may be any suitable type such as that disclosed in GB 2411763 A. The flood gun neutralizes the charge on the sample surface by replenishing the emitted electrons. The neutralization stabilizes and controls charging of the sample surface.

The apparatus may further comprise one or more video cameras 132, 133. These may be mounted outside of the vacuum chamber and configured to provide images of the sample stage. The video cameras may be mounted to collect images of the sample on the sample stage through an optical window in the vacuum chamber. In FIG. 2 two cameras are shown. Lamp 134 is shown illuminating the sample from above, for example in the same direction that electrons are ejected from the sample. Light from lamp 134 may be directed to the sample via a pair of mirrors 135, 136. Mirror 136 may be an annular mirror arranged such the emitted electrons from the sample pass through the central hole in the mirror. The pair of mirrors provide a periscope arrangement which allows convenient locating of the lamp. Camera 132 is arranged to view the sample from above using annular mirror 136. Mirror 135 is a one-way or semi-silvered mirror that reflects light from the lamp directed towards the sample but allows at least some of the light from the sample to be incident on the camera 132. Camera 132 has the advantage that by viewing the sample from directly above a good view of the surface from which electrons are emitted is provided. A second camera 133 may view the sample more directly but at a more acute angle so may not provide such a good view of the surface but in comparison to camera 132 which views via annular mirror 136 no image is lost. A secondary lamp 137 may be provided. Although not apparent from the schematic figure, this secondary lamp 137 may illuminate the sample from a similar direction as the camera 133 views the sample. Laser 160 may also be mounted outside of the vacuum chamber and the ablation pulses directed to pass through a window into the vacuum chamber to reach the sample 120. FIG. 3A shows more detail of an embodiment of the laser 160. The laser may comprise a femtosecond (f-s) laser source 210. In other embodiments, the laser may be a picosecond or nanosecond laser. The f-s laser source 210 may be based on a diode-pumped Yb-medium that is able to provide a range of pulses lengths, pulse wavelengths and pulse energies. The pulses output from the laser source pass through a series of optical components that tune the pulses and direct them at a target area on the sample surface, as shown in FIG. 3A. Beam expander 215 functions to size and collimate the beam appropriately for the flat-top shaper 220, which converts a Gaussian beam into a beam with a flat-top intensity profile. Mirror 225 directs the beam or pulses towards a variable attenuator 230 and polarisation adjustment optics 235. Variable attenuator 230 may be used to reduce beam power/energy, if required. Polarisation adjustment optics 235 may comprise a zero order half waveplate or zero order quarter waveplate and may be rotatable. In this way, the polarisation of the laser beam may be rotated (for linear polarised laser light) or converted to circular or elliptical polarisation, which are both shown in FIG. 3B. In some embodiments, it may be possible to use more than one of the aforementioned waveplates in series and/or it may be possible to use waveplates that operate at a different (non zero) order. It may be possible to use other birefringent materials, e.g. in the form of a prism. In general, the control of the polarisation state of the incident laser provides a method to suppress laser induced periodic surface structures (LIPSS) formation. There are different ways that such control of the polarisation may be realised in practice, wherein the key requirement is to control the phase difference between the orthogonal polarisation components of the incident laser beam at its operating wavelength. In this way, the polarisation of the laser beam may be rotated (for linear polarised laser light) or converted to circular or elliptical polarisation. This may be achieved through the use of a single, or a plurality of, zero or multiple order waveplate(s) or through the use of other types of single or multi-layer birefringent optical materials, waveguides and components. A second beam expander 240 may be placed before mirror 245 to adjust the spot size of the beam at focus. Although we describe the laser in terms of a beam, we generally mean pulses or a burst of pulses since a continuous wave beam is not generated by the femtosecond laser source. Mirror 245 directs the pulses through the focusing lens 250, which focusses the pulses to the desired spot size on the sample surface. The pulses pass through a window 255, such as a glass window, into vacuum chamber of the XPS or AES spectrometer such that the pulses are incident at the target area of the surface of the sample 260. Controller 280 may control the f-s laser source 210, the variable attenuator 230 and the polarisation adjustment optics 235 to set the laser parameters as desired. The controller may also control one or both of beam expander 215 and beam expander 240, as required. This embodiment of laser optics may achieve a smooth, flat bottomed crater and hence good profiling performance. A change in the linear polarisation direction achieved using the polarisation adjustment optics between pulses can minimise possible ripple morphologies, due to laser induced periodic surface structures (LIPSS) which may develop on the surface during profiling. The method may comprise incremental or continuous rotation of the angle of the linearly polarised laser beam during ablation or in between ablation shots. Alternatively, the method may comprise conversion of the linearly polarised beam into a beam with circular or elliptical polarisation. Sample rotation, polarisation rotation and/or polarisation conversion may reduce crater bottom roughness and/or enable deeper depth profiles to be achieved.

In some embodiments, the femtosecond laser has a wavelength of 1030 nm and a pulse length of 160 fs. Alternatively, the laser wavelength may be 515 nm. Shorter or longer pulses may also be used such as in the range 10 fs to 10 ps, or 10 fs to 1 ps, or even between less than 1 fs and 1 ns. The spot size of the laser pulses at the sample surface can be varied. In some embodiments, the spot size is in the range of around 50-150 μm. The energy of each pulse can be varied depending on the material and ablation volume required, such as between 10 nJ and 1000 μJ or more preferably between 50 and 500 μJ. In one embodiment, the energy of each pulse may be around 600 μJ. The pulse repetition rate may be varied. In some embodiments, a pulse repetition rate of up to around the order of 10 KHz may be used. By combining laser beam scanning and stage rastering depths of multiple hundreds of microns may be achieved.

The controller 180 may be configured to receive an input from a user to set the laser parameters appropriate for the sample under investigation. For example, the pulse energy, spot size and/or pulse duration may be adjusted to provide at the sample surface an energy above the ablation threshold for the material but below an energy or duration sufficient to cause damage to the remaining surface chemistry. The controller 180 may receive inputs from a user interface or from another computer. The inputs may comprise settings to adjust one or more of the spot size, pulse energy, pulse duration, pulse repetition frequency and wavelength. Alternatively, the inputs may provide an indication of an expected material or type of material. The controller may comprise algorithms, a look-up table, library or database, for example in the execution of a computer program on a processor of the controller, providing laser parameters optimised to ablate the surface while avoiding or minimizing damage to the underlying chemical composition for the expected material or type of material. The parameters may be further optimised to provide rapid ablation while minimizing damage to the underlying chemical composition.

A further method of determining how to adjust parameters of the laser for different sample materials is to perform a survey scan of the sample surface to be ablated. This may comprise performing a method of electron spectroscopy such as XPS or AES described herein. Other sample survey scan techniques may also be used. In one example, for a single layer sample a survey scan may determine the elemental components in the surface layer. A library of similar materials may then be used to optimise settings, such as one or more of fluence, frequency, pulse duration, wavelength, to achieve a desired ablation rate (i.e. nm per level or pulse) that the chemical information in the surface layer is retained. A pulse number may then also be set for the desired depth or level of the profile. Crater morphology, such as the size, shape and/or surface roughness or variation may also be taken into consideration. For multi-layered samples the approach for a single layer may be repeated for each layer. Alternatively for multi-layered samples, either prior knowledge of the layer-by-layer composition or a survey profile can be used to determine the laser parameters to use. For example, a survey profile may comprise an approximate assessment of composition, followed by use of a library of similar materials to optimise settings as for a single layer. Where the library is insufficient or inaccurate for the sample, ablation rates can be determined by ex-situ analysis (e.g. mechanical profilometry, microscopy or white light interferometry) of craters formed with varying fluence and pulse/level number.

Ablation rate (i.e. nm per level or pulse) is material dependant and can be determined by ex-situ analysis (e.g. mechanical profilometry, microscopy or white light interferometry) of craters formed with varying fluence and pulse/level number.

Returning to FIG. 2, the laser 160 and X-ray or electron source 130 are configured such that they respectively direct laser pulses and X-rays or electrons to the same target area on the sample surface, i.e. the laser pulses and X-rays or electrons are coincident on the sample surface. By alternate operation of the laser to remove a layer from the sample surface and the X-ray or electron source to irradiate the sample surface to cause electrons to be emitted from the sample, a compositional depth profile of the sample can be built. The use of a femtosecond laser is particularly advantageous as it avoids or reduces damage to the composition of the sample surface in comparison to ion beam sputtering.

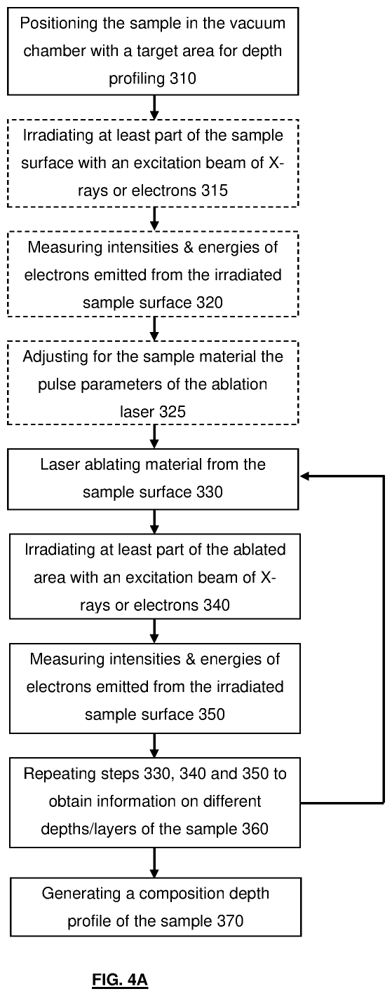

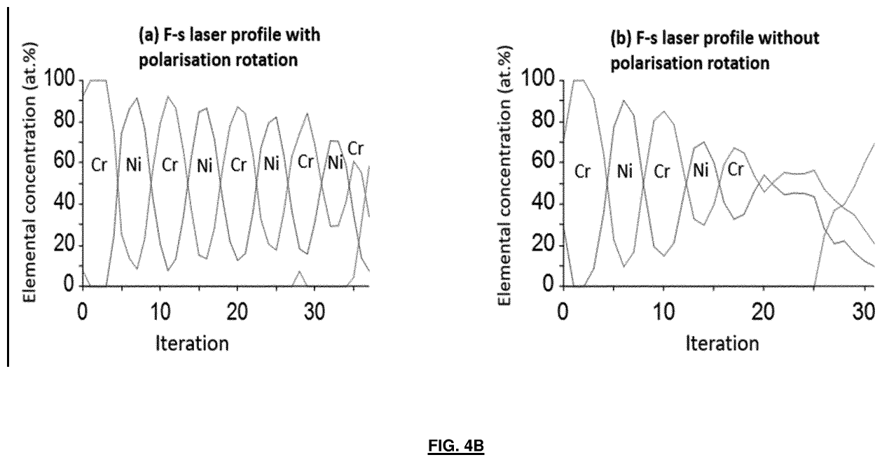

We now describe in more detail a method of operation of the apparatus of FIG. 2. FIG. 4A is a process flow chart of a method 300 of operating the apparatus of FIG. 2. The process starts at step 310 with positioning the sample in the vacuum chamber of the apparatus. This may comprise placing the sample on the sample stage in the chamber and moving the sample stage to position the sample such that ablation beams and excitation beams will be incident at a target area of the sample. The sample may be introduced to the chamber by breaking the vacuum to place the sample on the sample stage followed by evacuating the chamber, or the sample may be introduced via a vacuum load lock. The method may additionally or alternatively comprise adjusting the laser and X-ray or electron sources such that their beams are incident on the correct location on the sample. In one arrangement coarse alignment may be performed using positioners of the sample stage and fine alignment may be achieved by adjusting the positions of the laser and X-ray or electron source beams. Preferably, at step 315 prior to ablation an excitation beam of X-rays or electrons is generated and directed at the native surface of the sample. The X-rays or electrons may be directed at the native surface within an area that is to be ablated. Alternatively, at this step the X-rays or electrons may be directed at any area of the surface of the sample, such as outside the region to be ablated, for example if the sample has a uniform composition as is often the case for thin films. At step 320 the intensities and energies of the emitted electrons are measured using a detector and electron analyser. The emitted electrons of interest are photoelectrons and/or Auger electrons. Optionally, at step 325 the laser may be adjusted by controller 280 to tune the pulse parameters for the material of the sample. For example, the pulses may be adjusted to ablate more material rapidly or to reduce damage to the surface composition. Different materials may require lower pulse energies for ablation and/or may be damaged more easily for longer pulses. Although step 325 is shown in the figure as following the initial irradiation and measuring steps 315 and 320, this optional step may be performed at a different point or points in the method at any time before an ablation step, such as before or after optional steps 315, 320. At step 330 the laser generates pulses for ablating the sample surface. After ablation, as shown at step 340, an excitation beam of X-rays or electrons is generated and directed at the new surface generated by the ablation. This step is performed without the need to move the sample because the excitation beam and ablation pulses are substantially spatially coincident. At step 350 the intensities and energies of the emitted electrons are measured using a detector and electron analyser. The emitted electrons of interest are photoelectrons and Auger electrons. The steps of laser ablating, irradiating with an excitation beam and measuring electron intensities and energies may be repeated to build up compositional information on layers of the sample, as shown at step 360. Between each step of laser ablating 330, or between each laser pulse used in each step of laser ablating 330, the sample surface and/or the plane of polarisation of the laser beam is rotated in steps, e.g. 55 degrees. A degree of rotation between each laser pulse may be chosen so that LIPSS formation becomes effectively suppressed, which may be a rotation between 10 and 80 degrees, such as between 40 and 70 degrees, for example 55 degrees. Alternatively, the laser pulses may be converted to elliptical or circular polarisation in order to suppress LIPSS formation. At step 370 a compositional depth profile is generated or calculated.

We now describe in more detail the physical processes and advantages of using femtosecond laser ablation over other material removal techniques.

For laser ablation the material removal process is dependent on the laser pulse length, but involves two competing mechanisms: a thermal process, and an electrostatic process, also known as the coulombic explosion. In both cases, the laser photon energy is mainly absorbed by electrons. In the thermal process the excited electrons relax through electron-phonon interactions and the lattice equilibrates after some picoseconds through local heating. Material is ejected as a result of mechanisms which include evaporation and hydrodynamic expansion of heated material, with the actual mechanisms involved depending on the laser pulse length and energy. In the coulombic explosion mechanism, the strong electric field associated with the high intensity short pulse of light enables strong-field ionization and processes such as multi-photon and tunnel ionisation to occur, resulting in a high concentration of ions in the surface region. When the electrostatic attraction between ejected electrons or the electrostatic repulsion between the positively charged ions exceeds the local bond strength, the ions are ejected from the surface of the material in a coulombic explosion. As the laser pulse is shortened in length to the ultrashort femtosecond range, there is a greater decoupling of the electronic and solid relaxation process, due to there being insufficient time for these processes to occur. Consequently, the coulombic explosion dominates over thermal mechanisms for ultrashort pulse induced ablation.

The conventional techniques of monatomic and cluster ion sputtering have disadvantages compared to ultrafast laser ablation. In monatomic ion sputtering, the incident ions penetrate the surface layers, causing a momentum cascade with atoms in the local region. When sufficient energy is transferred to a surface atom such that bonds with neighbouring atoms can be broken, the surface atom is ejected (sputtered) into the vacuum. In cluster ion sputtering, the low average energy of the ions and the collision between ions in the cluster upon impact with the surface results in much less or no penetration of the incident ions, but still causes multiple collisions between surface atoms, again resulting in surface atoms being ejected into the vacuum. The high average energy per atom in monatomic sputtering leads to chemical damage of the surface to be analysed by XPS or AES. In polymers, this leads to effects such as preferential removal of functional groups and a modification in the bonding, resulting in a disordered graphitic-type carbonaceous structure. In inorganic materials, the chemical damage often takes the form of preferential sputtering, in which one element is preferentially sputtered compared to another element in the compound. The much lower average energy per atom in cluster ion sputtering results in much less or minimal damage in polymers, but still results in preferential sputtering effects in inorganic materials.

Preferential sputtering of one element in a compound over another is generally considered to be caused by two effects: namely the mass difference effect and the surface binding energy. The mass difference effect takes into account the variation in energy transfer to elements of different masses when incident ions enter the surface of a compound and this effect on the sputter yield for each element. The surface binding energy is the energy required to remove an atom from the outer surface atomic layer. The surface binding energy considers the variation in bond energies for different atoms in the compound and often the sublimation enthalpy for the surface composition is employed. Generally, for inorganic compounds, the mass difference effect is the predominant mechanism leading to preferential sputtering.

With femtosecond laser ablation, the high energy ultra-short pulse of the laser beam causes multiphoton ionisation promoting electrons from valence band into conduction band. Further absorption of energy through inverse bremsstrahlung, leads to avalanche ionisation and a space charge effect. The electrons are ejected into the vacuum. Electrostatic repulsion between the ions remaining in the surface region and attraction to the ejected electrons leads to a coulombic explosion, in which ions are ‘pushed out’ or ‘pulled out’ of the surface, resulting in ablation. For femtosecond laser ablation, absorption of the pulse energy occurs over such a short time frame that the energy is transferred to electrons, but not directly to phonons, giving rise to minimal heating.

In the laser ablation coulombic explosion mechanism, bonds are broken between the departing ions and underlying atoms, but there is likely to be no atom-to-atom momentum transfer as in the sputtering process. Hence there is no mass difference effect. Furthermore, it is not necessarily the surface layer of atoms which is ablated, so the surface binding energy is not of importance in the process. Consequently, neither of the two effects which lead to preferential sputtering in sputter depth profiling occur in laser ablation. Hence, using optimised laser parameters, analysis of the material surface following laser ablation can give rise to minimal or much less damage of the ablated crater surface compared to ion beam sputtering and a more accurate determination of surface composition by XPS/AES.

Femtosecond laser ablation is a very rapid process (10⁻¹⁵-10⁻¹² seconds) and the volume of material removed is dependent on the energy and spot size of the laser pulse and operation mode of the laser. The mode of operation of a pulsed laser can be varied from single pulses to repetitive pulses at different frequencies. The amount of material removed by a single pulse can range from a few nm to >500 nm, as the energy is increased. Hence, using laser ablation as the material removal process enables tens to hundreds of microns of material to be removed in practical time scales. Thus, XPS/AES depth profiles can be recorded over much larger depths and deep buried layers and interfaces exposed using laser ablation depth profiling, in contrast to sputter depth profiling, where accessing such depths are impractical.

An important process which occurs with repeated laser ablations of a surface is the formation of laser induced periodic surface structures (LIPSS), which exhibit a ripple morphology. The formation of LIPSS is a complex process, with different theories being proposed to explain the phenomenon [J. Bonse, S. Grãf Laser Photonics Reviews 14 (2020) 2000215]. The formation of LIPSS on the surface is an issue for electron spectroscopy depth profiling, as the ripple morphologies roughen the surface and potentially worsen the depth resolution of the depth profile, giving rise to layers not being clearly resolved and/or diffuse rather than sharp interfaces in the profile. One of the most accepted theories of LIPSS formation is that the incident light is scattered by the surface roughness [Bonse and Grãf, ibid.]. Other surface waves, such as surface plasmon polaritons, may also be excited. The incident radiation interferes with the primary scattered radiation and surface plasmon polaritons leading to a spatial variation of the incident beam energy distribution and a ripple morphology developing at the material surface as the number of ablation pulses increase. Many factors influence the different LIPSS structures formed including sample roughness, polarisation direction, angle of incidence and material dielectric constant [Bonse, and Grãf ibid]. As sample roughness and polarisation direction are important factors in LIPSS formation, various experimental and optical strategies can be employed to retard and limit LIPSS formation promoting the generation of a smoother crater bottom during the depth profile. To achieve this objective, one or more of the following is performed:
(i) in the optical set-up, the plane of polarisation of linearly polarised laser beam is:
   (a) continuously rotated;
   (b) converted to a circular or elliptically polarized beam prior to being incident on the sample; and/or
   (c) rotated step-wise by an angle between 0 and 360 degrees between each laser pulse, and/or
(ii) the sample is continuously rotated or rotated by an angle between 0 and 360 degrees between each laser pulse.
FIG. 4B shows the different depth resolutions obtained when depth profiling through a nickel/chromium multilayer structure with (left hand graph) and without (right hand graph) rotation of the laser polarization between pulses.

### Quantification

Electron spectroscopy instruments count the numbers (intensities) and energies of electrons emitted from the surface of a material following excitation by an energetic source (e.g. by X-ray, UV or electron irradiation). The total electron intensity is plotted as a function of the electron (binding or kinetic) energy. Quantification in electron spectroscopy is based on the direct relationship between the intensity of a photoelectron and/or Auger electron peak and the molar fractional concentration of the element within the analysis depth. This relationship is described in equation (1), where I is the peak intensity, J is the photon flux, p is the concentration of the atom or ion, σ is the cross-section for electron emission, K is the spectrometer factor and L is the electron attenuation length:

$$I = J ρσ KL \qquad ( 1 )$$

The cross-section for emission σ is the probability that a photoelectron or Auger electron will be emitted from exposure to the energetic source. The cross-section will vary with element, electron orbital and total angular momentum. The spectrometer factor K accounts for variation in detector performance from instrument to instrument, and incorporates both a transmission function (i.e. proportion of electrons transmitted through the detector as a function of kinetic energy) and detector efficiency (i.e. the proportion of transmitted electrons that contribute to the detected signal). Inelastic mean free path describes the distance travelled by the emitted electron before being inelastically scattered. However, in equation (1) the more accurate term attenuation length, L, is used which corrects the inelastic mean free path for elastic scattering and allows the intensities emitted in a given direction from a given depth to be determined. Inelastic scattering results in the electron not contributing to the photoelectron and/or Auger electron peak intensity.

The contributions of each of the above factors (σ, K, L) to the photoelectron/Auger electron peak intensity for any specific peak in the spectrum are combined into a single term, known as the sensitivity factor, F, which allows the relative proportion of that element in the analysis depth to be determined (see equation (2) below). The sensitivity factor can be taken from a library of theoretically determined values, experimentally determined values or user determined values. In the case that the library values have been determined on/for an electron spectrometer with a different transmission function, then a correction for that different transmission function will be required.

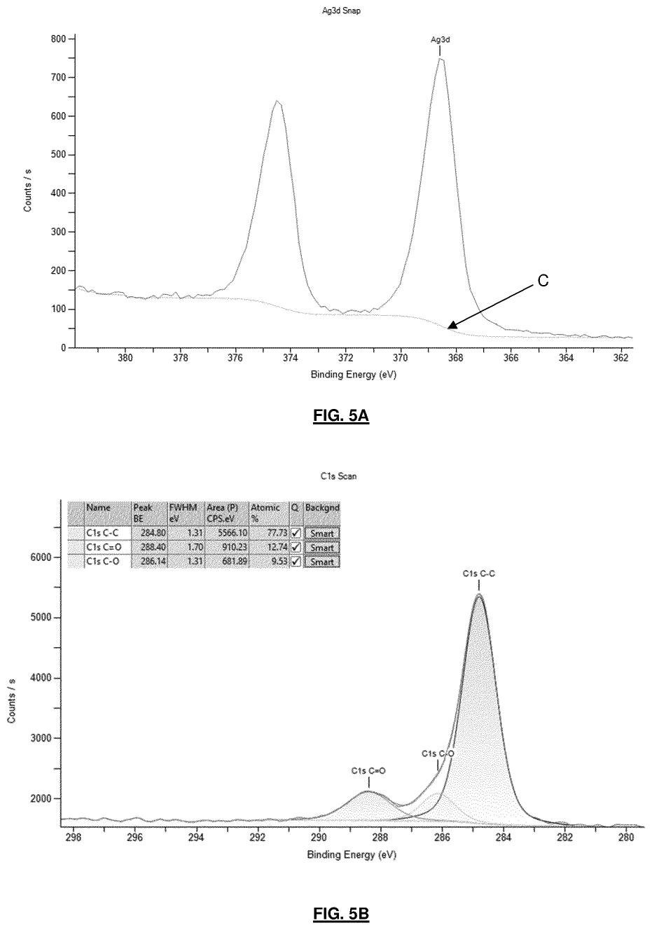

The peak intensity is usually measured graphically as the integrated area of a photoelectron and/or Auger electron peak, following subtraction of the background signal using a suitable method. FIG. 5A shows the Ag 3d photoelectron peak. The background, C, is calculated using different methods, including linear, Shirley or Tougaard. There are other methods for determining the peak intensity, such as the use of peak height instead of peak area and measurement of the peak-to-peak differentiated spectrum, encountered in electron excited Auger spectroscopy.

Using equation (1), and given a constant photon flux, the normalised peak intensities can be used to calculate the elemental concentration as atomic percent on the assumption that there is a homogenous mixture of elements within the analysis depth. The concentration of element A within a multi-element material, based on this assumption, is given by equation (2):

$$[ A ] at \% = [ ( {I}_{A} / {F}_{A} ) / Σ ( I / F ) ] \times 100 \qquad ( 2 )$$

I and F represent the peak intensities and sensitivity factors of elements detected in the spectrum (I_{A} is the peak intensity of element A, F_{A} is the sensitivity factor of element A). However, corrections due to matrix effects will be required in the case of Auger electrons generated using an electron source. It is assumed that the sample comprises a homogeneous mixture of elements within the analysis depth for the quantification of photoelectron and Auger electron spectra, although other methods can be used which give a more accurate description of the elemental distributions within the analysis depth, if it is known or expected that such elemental distributions occur within the analysis depth.

Convolution of peaks can occur due to the presence of overlapping energy peaks or multiple chemical states. This is shown in FIG. 5B. To quantify the different chemical states in such cases, it is necessary to perform peak fitting to separate the peak intensity contributions from the various components present and then quantify these separately, as described in the preceding paragraphs. The binding/kinetic energies for different chemical states of an element are determined from recording standard spectra of such materials with known compositions or from available spectroscopic libraries. FIG. 5B shows an example of the C 1s region from an XPS spectrum, containing contributions from carbon in different chemical states, C—C, C—O and C═O. Peak fitting has been used to determine the relative peak intensity corresponding to each chemical state, allowing quantification of the various chemical states. The relative atomic concentrations of C—C, C═O and C—O respectively are 77.73%, 12.74% and 9.53%.

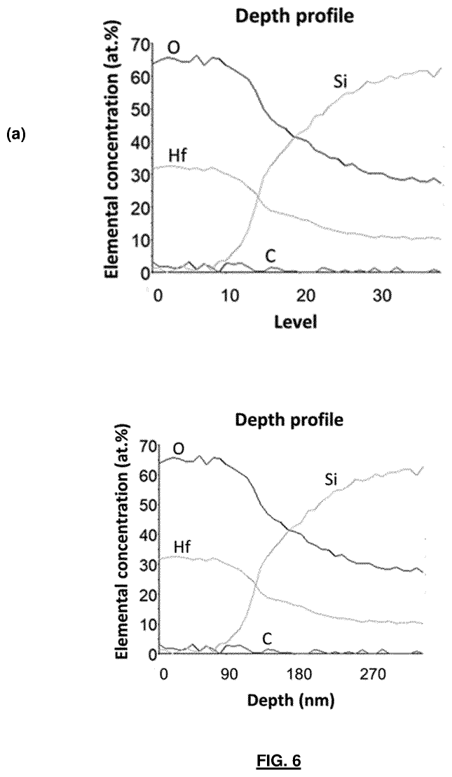

To construct a depth profile, the electron spectroscopy spectra are recorded from the surface and following each laser ablation cycle. The spectra are quantified and the chemical composition, based on equation (2), is determined. For the surface and at each cycle/depth where electron spectra have been recorded, the fractional composition of each element or elemental chemical state is plotted as a function of the number of laser ablation cycles or depth. The conversion of number of cycles into depth can be performed by measuring the depth or through prior knowledge of the layer thickness. FIGS. 6a and 6b respectively show an example of a quantified laser ablation XPS depth profile, plotted as a function of ablation level and depth.

### Crater Formation

We have described above how the ablation beam and excitation beam are spatially coincident at the sample surface. If the excitation beam is larger than, or a similar size, in terms of its area incident at the ablated sample surface region then the excitation beam may be incident on the edges or sidewalls of the ablated region. This may cause electrons to be emitted and analysed that originate from the edges or sidewalls in addition to electrons emitted from surface that is desired to be studied. These electrons from the edges or sidewalls may be from different chemical components than the crater surface desired to be studied and, hence, may cause inaccuracies in the measurement. Accordingly, it is desirable that the ablated region has a larger area than the area of the excitation beam when incident on the sample surface.

One approach to increase the surface area of the ablated region is to scan the ablation beam across the sample surface. Another approach is to use a wider beam to ablate a larger area. We will now describe these options.

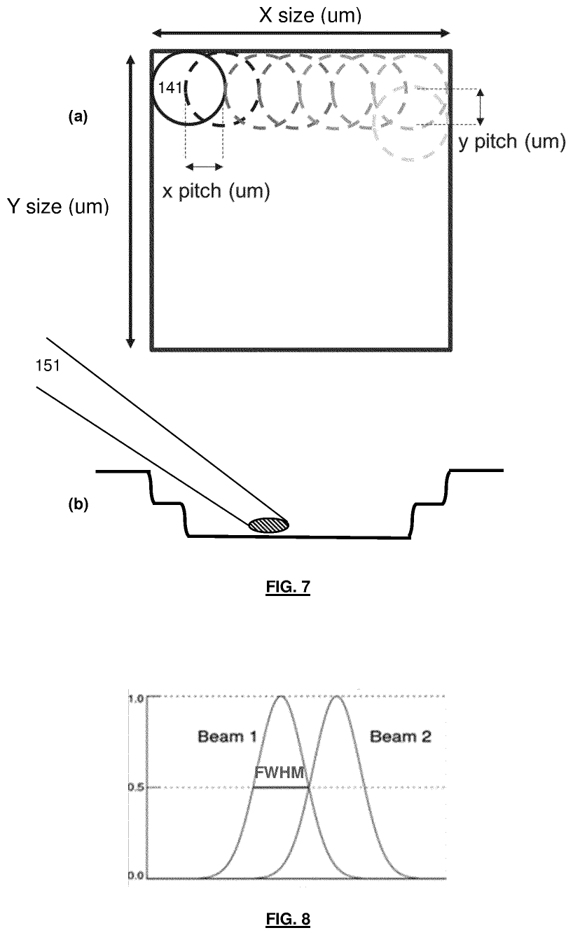

FIG. 7a is a schematic diagram of a beam scanning approach to produce a larger ablated area at the sample surface. The focused laser pulses 141 from laser 130 are raster scanned in a box pattern. The scanning is made up overlapping pixels. Each pixel may be ablated by one or more pulses and then the pulse position is moved to the next pixel. The number of pixels required is determined by the dimensions of the area to be ablated and pitch from pixel to pixel. In FIG. 7 the area to be ablated has a width of X μm and length of Y μm. The pixel pitch is respectively x μm and y μm in the width and length directions. At each pixel the laser delivers a single pulse or multiple pulses at a given repetition rate. The process may be repeated, and crater depth increased, by setting a given number of passes for the box pattern to complete. The sample can also be rotated a given angle about the centre point of the raster area in between passes in order to reduce crater bottom roughness. For example, on a first scan the pulse position is first moved in the x direction and after a set of x pixels is completed, the position is stepped in the y direction and these steps are repeated to build up the raster scan of the area XY. For the next layer the scan process may be rotated by 90° such that the first scan of pixels is in the y direction and the position is then stepped in the x direction. Other scan patterns are possible.

The beam may be moved across the sample by including a movable mirror in the optics, for example at mirror 260 in FIG. 3A. In one embodiment it is desirable that the maximum area is 2 mm² but this could be larger in other embodiments. Larger areas are useful for accessing deeper layers by overcoming aspect ratio issues that might be present with smaller areas. However, larger areas will take longer to ablate.

FIG. 8 is a schematic representation of a Gaussian beam overlap that may be used to achieve uniform intensity of radiation on a sample surface for ablation. The figure shows a possible beam overlap condition, based on the full width at half maximum (FWHM) to achieve uniform intensity of radiation across the rastered area and hence a flat bottom crater. As shown in the figure the beams at two adjacent pixel positions overlap such that the position of the FWHM for one pixel position just contacts the FWHM for the adjacent position.

FIG. 7b is a schematic cross-sectional view of the crater depth showing a flat-bottom profile. For comparison a narrower width excitation beam such as an X-ray beam is shown at 151.

For an X-ray spot size range of 10-400 μm it would be preferable to use the maximum spot size possible while keeping to a recommended 5:1 ratio of crater width to X-ray spot size. The centre of the X-ray spot for the XPS analysis is positioned in the centre of the crater.

Instead of scanning the beam while keeping the sample position fixed as described above, an alternative approach is to move the sample and keep the beam position fixed. The pulses of the laser are focused to a fixed point in x-y-z, which is co-incident with the X-ray beam focus point. The sample stage is raster scanned with a laser ablation step at each pixel in a similar manner to the above. After each pass the stage is moved back to the centre point of the raster area in order to perform the XPS analysis. Again, the sample can be rotated a given angle about the centre point of the raster area in between passes in order to reduce crater bottom roughness.

For AES analysis the electron beam focus position is also centred on the centre of the crater and a similar recommended spot size ratio as set out above applies.

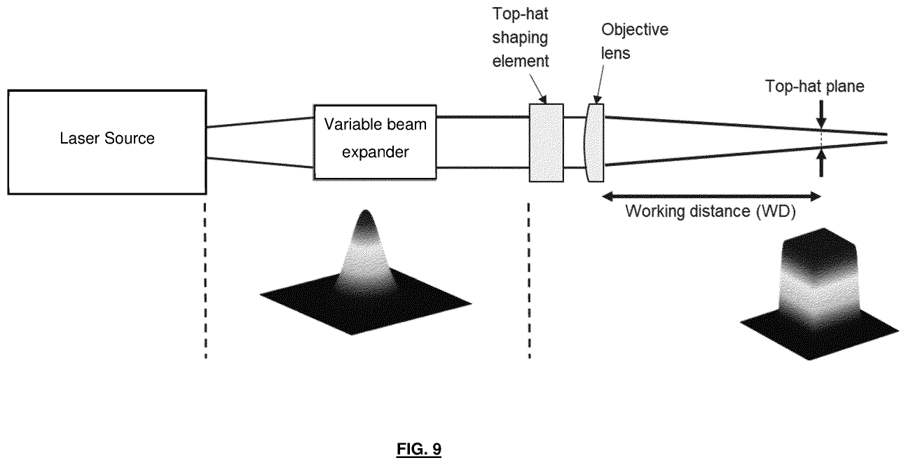

As mentioned above, another alternative approach is to use a wider beam to ablate the area. FIG. 9 is a schematic representation of the optical setup to produce a top-hat shaped beam or pulse intensity. A top-hat (or flat-top) beam profile is formed using a diffractive optical element (DOE) beam shaping element as part of the optical setup. As shown in the figure the top-hat intensity profile is formed near to, but not at, the minimum focused spot position. The laser pulses are first passed through a beam expander to increase the cross-sectional area of the beam. This may correspond to beam expander 215 in FIG. 3A. The incident Gaussian beam (TEM₀₀) is sized and collimated using the variable beam expander to the nominal 1/e² diameter required by the selected DOE element. The top-hat or flat-top beam shaping element may correspond to flat-top shaper 220 in FIG. 3A. The Gaussian intensity profile is converted to a uniform-intensity spot of either round, square or rectangular shape at a given working distance from an objective focusing lens. The spot size is determined by the incident beam size, the incident beam wavelength and the effective focal length (EFL) of the focusing lens.

With this approach the maximum uniform top-hat area is likely to be approximately 500 μm×500 μm. Without combining this approach with one of the above scanning processes, the maximum ablated area will therefore also be approximately 500 μm×500 μm. Using the ideal crater width to X-ray spot size ratio of 5:1, this would allow for an X-ray spot size of up to 100 μm such as in the range of 10-100 μm.

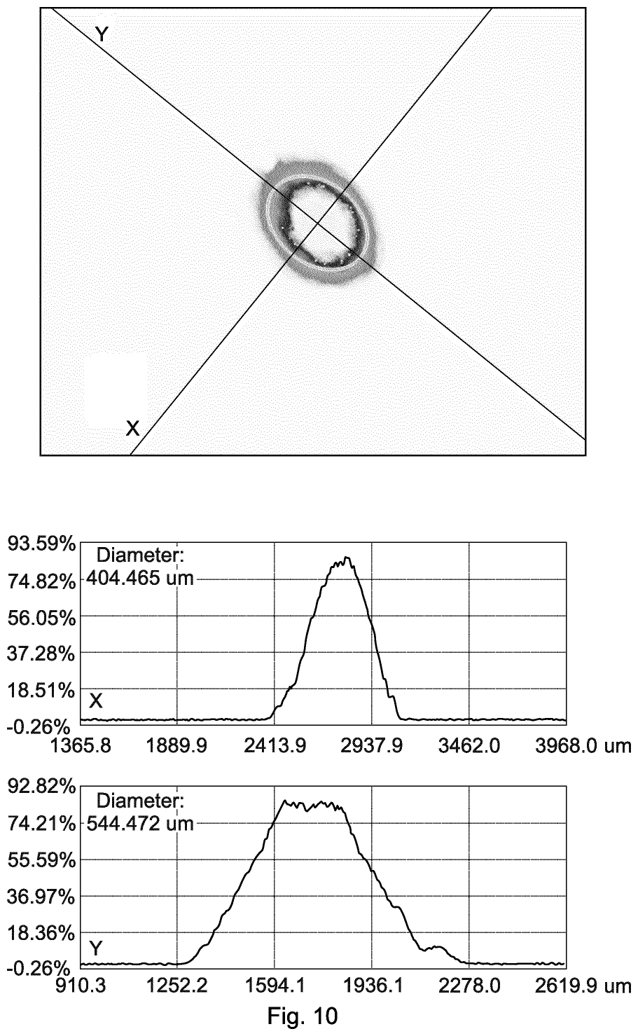

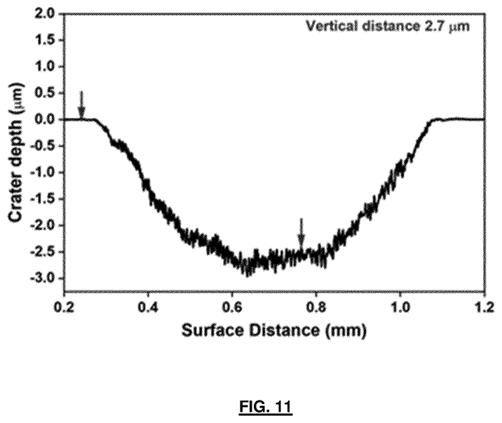

FIG. 10 shows a top-hat profile achieved for generating an oval-shaped crater, resulting from the laser being angled at 45 degrees to the sample surface. In general, the laser can be angled at any angle of incidence between 0 and 90 degrees, such as between 30 to 60 degrees, to the sample surface. In this figure the flat-top was achieved at a position after the focal plane and not before the focal plane as shown in FIG. 9. In the upper plot of FIG. 10 the solid oval line indicates the FWHM. In the lower figure the intensity profiles are taken along the X and Y directions of the upper figure. The FWHM in the X-direction is around 404 μm and in the Y-direction is around 544 μm.

FIG. 11 shows an example mechanical profilometry trace over the central region of a crater formed on a GaAs single crystal sample using the beam profile in FIG. 10. In this example the beam profile was scanned across the sample surface. In FIG. 11 a 3×3 pixel stage raster was used with a 200 μm x/y pitch. A single shot was applied per pixel with 15 levels of ablation and a 90 rotation between levels. The pulse energy was approximately 200 μJ per pulse. The pixel positions had approximately 50% overlap resulting in a smooth crater bottom surface. A greater crater depth could be achieved with less overlap because it would lead to removal of more material, but this would be at the expense of increased crater surface roughness.

A benefit of using a scanned approach (i.e. scanning the beam or the stage) compared to a stationary beam approach (i.e. either Gaussian or top-hat) is an increase in the maximum achievable crater size. The maximum depth of profiling may therefore also be increased because the resulting crater aspect ratios allow access for the X-ray and flood gun beams to the crater floor at greater depths. This may allow depths in the multiple hundred micron range. Conversely, a drawback with the scanned approach is an increase in ablation times with increasing pixel number. Additionally, careful determination of pixel pitch may be needed to avoid a rough crater bottom from the overlapping pulses, which may also lead to reduced depth resolution. A combination of scanned and stationary approaches may be preferred where access to the crater floor for the X-ray and flood gun beams is provided by milling channels around a stationary beam crater using the scanning approach. With the scanning approach the typical beam sizes and therefore pulse energies may be reduced compared to a stationary beam approach. For example, beam diameters may be in the range 10-100 um with pulse energies in the range 0.01-10 μJ for the scanned approach, whereas beam diameters may be in the range 100-500 μm with pulse energies in the range 10-1000 μJ for the stationary beam approach. Lower pulse energies in the range may require multiple pulses in a burst at each pixel and/or level, using repetition rates in the range 0.001-200 KHz.

### Results

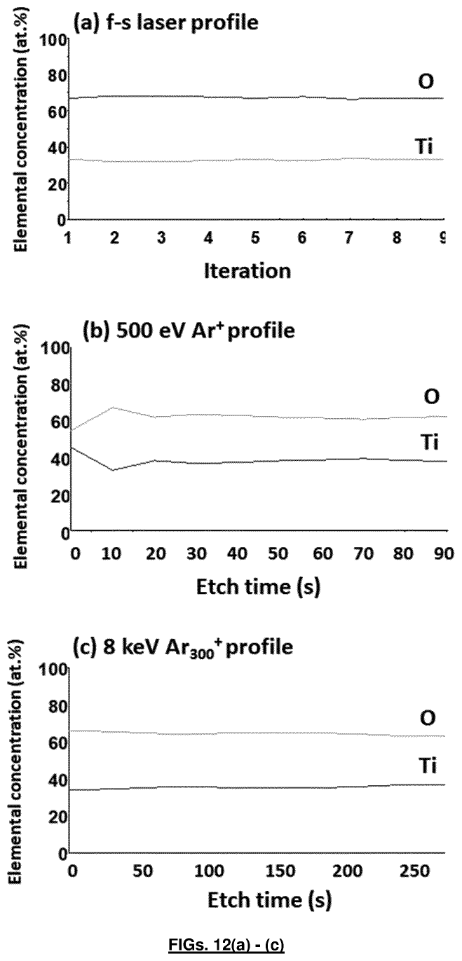

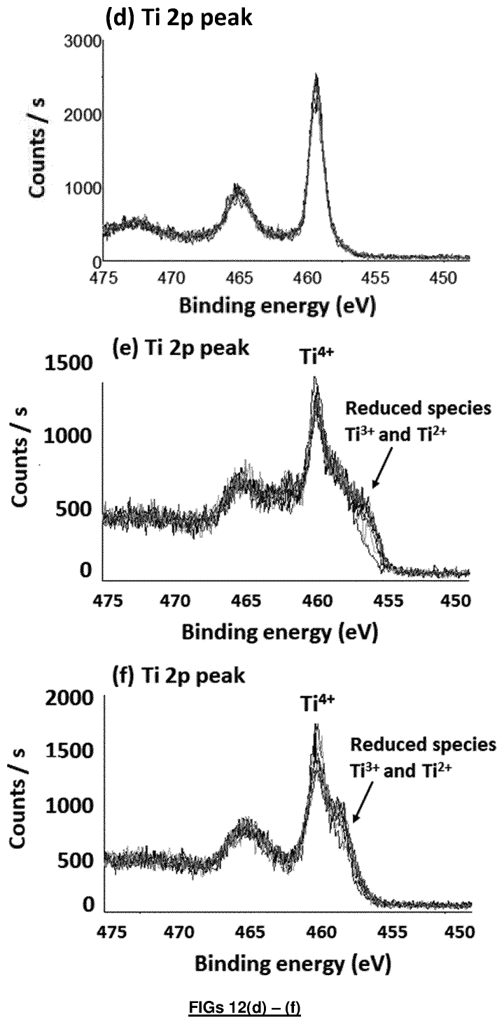

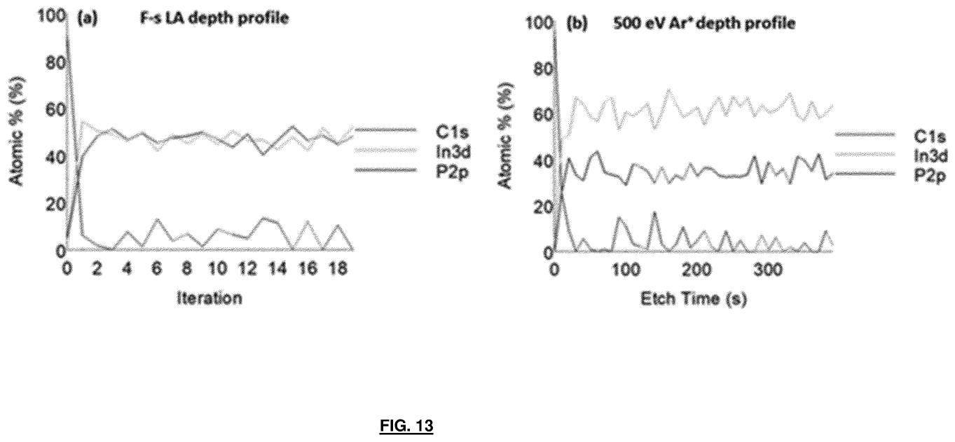

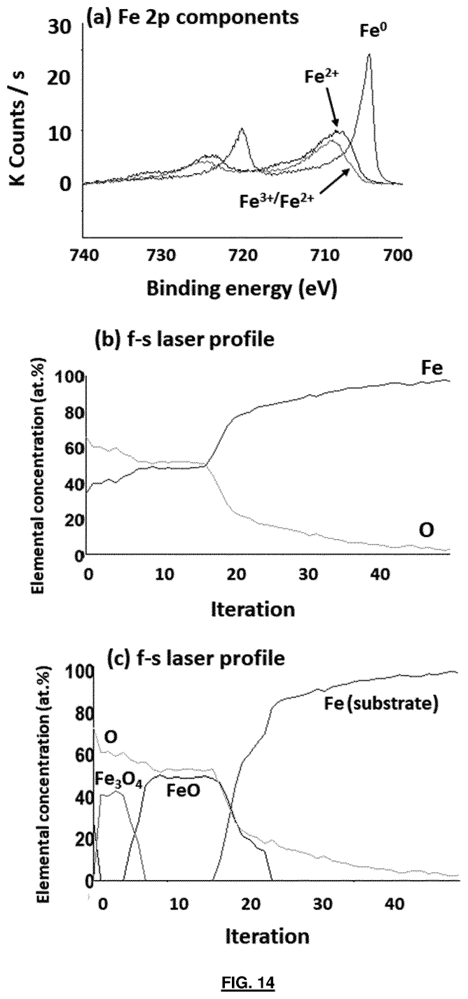

FIGS. 12-15 show results of using the laser apparatus shown in FIG. 3A for femtosecond laser ablation XPS depth profiling. The laser pulse duration used in each case was 160 fs and the wavelength was 1030 nm. Comparisons to sputter depth profiling are also provided. FIGS. 12 and 13 show how the use of femtosecond laser ablation avoids preferential sputtering effects for two technologically important inorganic materials, TiO₂ and InP.

FIG. 12 shows the XPS depth profile obtained for a bulk TiO₂ sample. FIG. 12a shows the compositional depth profile obtained using femtosecond laser ablation for nine ablation levels (energy per pulse 120 μJ). FIG. 12b shows the compositional depth profile obtained using conventional sputtering with a 500 eV argon ion beam. Compositional data was recorded after ten seconds of etching and the etching-measure cycle was continued in ten second etch periods up to a total time of 90 seconds. FIG. 12c shows the compositional depth profile obtained using conventional sputtering with an 8 keV 300 argon atom GCIB. Compositional data was recorded after 30 seconds of etching and the etching-measure cycle was continued in 30 second etch periods up to a total time of 270 seconds. The elements and their chemical states in the sample are determined using XPS based on the intensities and energies of emitted electrons.

As shown in FIG. 12(d), for the Ti 2p peak, the chemical state of Ti in TiO₂ is Ti⁴⁺ which has a binding energy of 459.0 eV. FIGS. 12(e) and 12(f) show lower oxidation states of Ti, namely, Ti³⁺ and Ti²⁺ which have binding energies of 457.7 eV and 456.5 eV respectively, as we shall explain below.

The sample composition at the surface (initial time period) is different to that following the first ablation/ion etch due to the presence of surface hydrocarbon contamination. The hydrocarbon XPS C 1s contamination signal has been removed from the profile as it is not relevant to determination of the TiO₂ stoichiometry. Measurements after the initial time period relate to bulk TiO₂. In FIG. 12a the O concentration can be seen to be 67 at. % and the Ti concentration 33 at. % resulting in a stoichiometry of TiO_{2.0} for the femtosecond laser ablation method. In FIG. 12b and FIG. 12c the concentration of O is approximately 62 at. % and Ti approximately 38 at. %. Hence, the stoichiometry is determined to be TiO_{1.65} for 500 eV Art ion sputtering and TiO_{1.70} for 8 keV Ar₃₀₀⁺ cluster sputtering, which are both incorrect. The Ti 2p spectra (FIGS. 12d-f), show the presence of only Ti⁴⁺ for the femtosecond laser profile (FIG. 12d), as expected for TiO₂ but for both 500 eV Art ion sputtering (FIG. 12e) and the 8 keV Ar₃₀₀⁺ cluster sputtering (FIG. 12f), the presence of Ti³⁺ and Ti²⁺ states are clearly observable, due to the preferential sputtering of O as a result of ion beam bombardment.

FIG. 13 shows similar compositional depth profiles for InP_{1.0}. FIG. 13a shows the profile produced using femtosecond laser ablation with approximately 120 μJ pulses over 18 iterations. FIG. 13b shows the profile produced for 500 eV argon ion sputtering over 390 seconds. For the femtosecond laser ablation, the concentrations of In and P are very similar at 50 at. % whereas for sputtering the concentration of In is substantially higher than that of P. The result is that for the femtosecond laser depth profile the recorded stoichiometry is InP_{1.0}, whereas for sputtering it is InP_{0.7}. This is due to the preferential sputtering of P from the sample.

To show the rapid depth profiling capability and ability to extend the femtosecond laser ablation XPS technique to many microns in depth we present in FIG. 14 an analysis of an iron oxide layer. Femtosecond laser ablation XPS depth profiling was performed for a ≈7 μm layer of iron oxide layer grown on iron. The sample received approximately 100 ablations (4 at each iteration level) at an energy of ˜300 μJ per pulse (with a 1 second pause between laser shots). After this the iron substrate was reached. Each laser ablation shot removed about 70 nm of material and, excluding the XPS analysis time, the profile was performed in approximately 1.5 minutes. As shown in FIG. 14b, the metal oxide exhibits two distinct layers, the outer layer showing a higher O concentration and an inner layer with a lower O content. FIG. 14a shows Fe 2p spectra from the 3 different regions, the outer layer, the inner layer and the substrate. The Fe⁰ spectrum is that from the iron metal substrate. The other two spectra exhibit spectral features (peak shift and shake-up satellite) which are indicative of different chemical forms of iron oxide in the layer, namely Fe²⁺ (FeO) and Fe²⁺/Fe³⁺ (Fe₃O₄). The Fe₃O₄ is evident for the first four ablation iterations which then transforms to FeO from around ablation iteration 8 to 18. From iteration 18, the oxide signal rapidly decreases as the underlying Fe is approached. Hence, as can be seen from the figure, important chemical information has been retained. Principal component analysis identifies the ‘fingerprint spectra’ associated with the different chemical states of Fe and can be used extract the regions within the profile where those individual spectra are present. Thus, in FIG. 14c, the chemical composition of each layer can be plotted and the Fe₃O₄/FeO layered structure of the oxide becomes apparent. For comparison, a high current, rapid etch rate using a 500 eV argon ion beam would etch at a rate of the order of 10 nm/minute, giving a total etching time of 700 minutes (11.7 hours) for a similar depth. Furthermore, iron oxide undergoes preferential sputtering of O, with Fe³⁺ species being reduced to Fe²⁺ and even metallic Fe under ion beam bombardment, so the important chemical information of the different oxides formed would not be retained with sputter depth profiling.

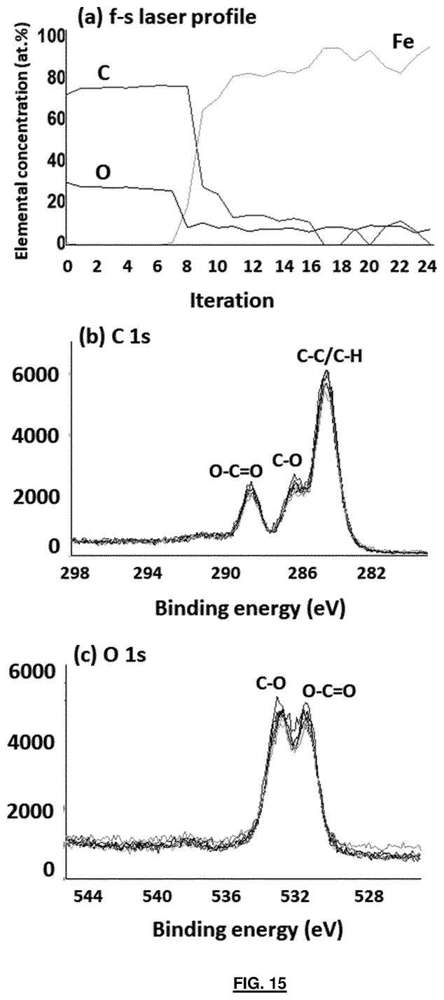

A further example of the advantages of the femtosecond laser ablation XPS technique is shown in FIG. 15 relating to a polymer sample, namely PET. The sample is a 12 μm layer on steel. FIG. 15a shows 24 iterations of femtosecond laser ablation at a single shot pulse energy of 300 μJ per iteration. The total time for this ablation and measurement sequence was around ten minutes. With increasing number of iterations, so increasing depth into the PET layer, the carbon: oxygen ratio remains constant indicating that there is no chemical change at increasing depth. After 7-8 pulses the presence of iron in the steel rapidly emerges. FIGS. 15b and 15c respectively show the C 1s and O 1s spectra for the first 7 to 8 iterations of ablation. Good uniformity between traces in each plot is seen, which shows the correct chemical states and relative intensities for PET, with no indication of chemical damage. The 7-8 iterations of ablation and measurement were achieved after around 2.5 minutes. In comparison, to retain the PET chemical information, as seen in the C 1s and O 1s XPS spectra for femtosecond laser ablation, argon ion cluster sputtering is required and after three hours of sputtering without including XPS measurement time, the etch depth reached would be around 5 μm only.

The person skilled in the art will readily appreciate that various modifications and alterations may be made to the above described methods and apparatus. The modifications may be made without departing from the scope of the appended claims. For example, the pulse parameters of the ablation laser or size and shape of the ablated area may be changed. Steps of methods from different embodiments may be combined and alternative components may be used in the ablation laser.

Embodiments of the present invention are set out in the following clauses:
A1. A method of determining a chemical composition of a sample using electron spectroscopy, the method comprising:
   ablating material from an area on a surface of a sample by irradiating the area with one or more pulses of a laser;
   irradiating at least part of the area with an excitation beam of electrons or electromagnetic radiation;
   measuring intensities and energies of electrons emitted from the at least part of the area of the sample as a result of the excitation beam; and
   repeating the steps of: ablating material, irradiating with the excitation beam, and measuring intensities and energies, to determine a quantitative surface depth profile of the chemical composition of at least part of the sample.
A2. The method of clause A1, further comprising, prior to the first ablating of material from the area, irradiating at least part of an unablated area with an excitation beam of electrons or electromagnetic radiation and measuring intensities and energies of electrons emitted from the at least part of the unablated area of the sample as a result of the excitation beam.
A3. The method of clause A1 or clause A2, further comprising determining, from the intensities and energies of the emitted electrons, the chemical state of the elements in the chemical composition.
A4. The method of any preceding clause, further comprising determining a depth or relative depth of the ablated area or areas.
A5. The method of any preceding clause, wherein the one or more pulses of a laser beam each have a duration less than 1 ns or less than 1 ps.
A6. The method of any preceding clause, further comprising repeating the step of ablating material, irradiating with the excitation beam, and measuring energies and intensities of emitted electrons, to determine a depth profile down to a depth greater than 5 μm.
A7. The method of any preceding clause, wherein each step of ablating material comprises removing a layer having a thickness in the range 0.3 nm to 1 μm.
A8. The method of any preceding clause, wherein the excitation beam is a beam of X-rays.
A9. The method of any preceding clause, wherein the excitation beam is a beam of X-rays and the spectroscopy is XPS.
A10. The method of any preceding clause, further comprising tilting the sample with respect to the ablation laser beam.
A11. The method of any preceding clause, further comprising (i) rotating the sample in a plane of the surface of the sample between the steps of ablating and/or between the laser pulses, and/or either (ii) rotating a plane of polarisation of the laser pulses between the steps of ablating and/or between the laser pulses or (iii) converting a polarisation of the laser pulses into circular or elliptical polarisation
A12. The method of any preceding clause, wherein the one or more pulses ablate material by coulombic explosion.
A13. The method of any preceding clause, wherein the step of ablating material forms a crater in the surface of the sample, and wherein the at least part of the area irradiated with an excitation beam of electrons comprises an area at the bottom of the crater.
A14. The method of clause A13, wherein the crater has a substantially flat bottom, and the excitation beam irradiates at least part of the substantially flat bottom.
A15. The method of clause A14, wherein the excitation beam irradiates the at least part of the substantially flat bottom and not the edges or sidewalls of the crater.
A16. The method of any of clauses A13 to A15, wherein the width of the substantially flat bottom of the crater is greater than the width of the excitation beam.
A17. The method of any of clauses A13 to A16, wherein the step of ablating material from an area of the sample comprises moving the relative position of the laser pulses to scan the pulses over the area on the surface of the sample to ablate the crater in the surface.
A18. The method of clause A17, wherein the relative position of the laser pulses is moved by scanning the laser or by scanning the position of the sample.
A19. The method of clause A17 or A18, wherein the scanning comprises irradiating the sample with one or more pulses at a plurality of partially overlapping pixel positions.
A20. The method of any preceding clause wherein the laser is incident at a non-normal angle to the surface to be ablated such as between 30 and 60 degrees.
A21. The method of any of clauses A13 to A20, further comprising passing the laser pulses through a beam-shaping element to convert the laser-pulses to have a substantially flat-top or top-hat intensity profile across its diameter incident at the sample surface.
A22. The method of any of clauses A13 to A21, further comprising passing the laser pulses through polarisation adjustment optics to change a direction of linear polarisation of the laser beam or to convert a linear polarisation of the laser beam into circular or elliptical polarisation of the laser beam.
A23. The method of clause A21 or A22, wherein the beam-shaping element comprises a diffractive optical element or refractive optical element.
A24. The method of any preceding clause, wherein laser pulses each have a duration less than 1 ns, less than 1 ps, less than 500 fs, less than 100 fs, less than 10 fs or less than 1 fs.
A25. The method of any preceding clause, wherein the energy per laser pulse is in the range 10 nJ to 1000 μJ, such as between 50 and 500 μJ.
A26. The method of any preceding clause, wherein the spot size of the laser pulse at the sample surface is in the range 1 to 1000 μm.
A27. The method of any preceding clause, further comprising:
   setting, by a controller, one or more parameters of the pulses of the laser based on composition information about a sample; and performing the step of ablating material, wherein the parameters of the laser pulses are set by the controller.
A28. The method of clause A27, wherein the one or more parameters of the laser pulses set by the controller comprise one or more of: pulse duration, pulse energy, repetition frequency, wavelength and spot size.
A29. The method of clause A27 or A28, wherein the step of setting further comprises: receiving an input from a user indicating the composition information about the sample; and the controller adjusting the one or laser parameters based on the composition information.
A30. The method of clause A27 or A28, further comprising:
   performing a survey scan or survey profile to determine an approximate measure of elemental components in the sample; and
   generating the one or more parameters of the laser pulses based on the approximate measure.
A31. The method of any of clauses A27 to A30, further comprising performing mechanical profilometry, microscopy or white light interferometry of the sample surface; and generating or adjusting the one or more parameters of the laser pulses based on the profilometry, microscopy or white light interferometry.
A32. The method of any of clauses A27 to A31, further comprising the controller using a reference database or algorithm to determine the laser parameters based on the information about the sample.
A33. The method of any of clauses A27 to A32, further comprising following steps of ablating material, irradiating with an excitation beam and measuring electron intensities and energies, adjusting the one or more parameters of the laser based on measured or predicted composition information about the sample at a depth following the ablation, and repeating the steps of ablating material, irradiating with an excitation beam and measuring electron intensities and energies using the adjusted one or more parameters of the laser.
A34. The method of clause A33, further comprising repeating the steps of adjusting, ablating material, irradiating with an excitation beam and measuring electron intensities and energies until the sample has been analysed to a target depth.
A35. The method of any preceding clause, further comprising placing the sample on a sample stage in a vacuum chamber and following the steps of ablating material, irradiating with the excitation beam, and measuring intensities and energies of emitted electrons,
   wherein the sample is not moved by an amount greater than the size of the sample between the step of ablating and the step of irradiating with an excitation beam.
A36. The method of any preceding clause, wherein the laser pulses and excitation beam are spatially coincident at the sample surface.
A37. The method of clause 35, wherein the step of ablating comprises raster scanning the ablation laser pulses relative to the sample surface, and wherein the excitation beam is coincident with the ablated sample surface.
B38. A method of electron spectroscopy, comprising:
   ablating material from an area on a surface of a sample by irradiating the area of with one or more pulses of a laser, wherein the ablation forms a crater in the surface of the sample;
   irradiating at least part of the ablated area at the bottom of the crater with an excitation beam of electrons or electromagnetic radiation;
   measuring intensities and energies of electrons emitted from the at least part of the area of the sample as a result of the excitation beam; and
   determining a chemical composition of the surface of the crater based on the measured intensities and energies of the emitted electrons.
C39. A method of electron spectroscopy, comprising:
   ablating material from an area on a surface of a sample by irradiating the area of the sample with one or more pulses of a laser, wherein the laser pulses have a duration less than 1 ns, less than 1 ps, less than 500 fs, less than 100 fs, less than 10 fs or less than 1 fs;
   irradiating at least part of the ablated area with an excitation beam of electrons or electromagnetic radiation;
   measuring intensities and energies of electrons emitted from the at least part of the area of the sample as a result of the excitation beam; and
   determining a chemical composition of the surface based on the measured intensities and energies of the emitted electrons.
D40. A method of electron spectroscopy, comprising:
   setting, by a controller, one or more parameters of pulses of a laser based on composition information about a sample;
   ablating material from an area on a surface of the sample by irradiating the area of the sample with one or more pulses of the laser, wherein the parameters of the pulses have been set by the controller;
   irradiating at least part of the area with an excitation beam of electrons or electromagnetic radiation;
   measuring intensities and energies of electrons emitted from the at least part of the area of the sample as a result of the excitation beam; and
   determining a chemical composition of the surface based on the measured intensities and energies of the emitted electrons.
E41. A method of electron spectroscopy, comprising:
   placing a sample on sample stage in a vacuum chamber;
   ablating material from an area on a surface of the sample by irradiating the area of the sample with one or more pulses of a laser;
   irradiating at least part of the area with an excitation beam of electrons or electromagnetic radiation;
   measuring intensities and energies of electrons emitted from the at least part of the area of the sample as a result of the excitation beam;
   determining a chemical composition of the surface based on the measured intensities and energies of the emitted electrons;
   wherein the sample is not moved by an amount greater than the size of the sample between the step of ablating and the step of irradiating with an excitation beam.
F42. A method of electron spectroscopy, comprising:
   placing a sample on sample stage in a vacuum chamber;
   ablating material from an area on a surface of the sample by irradiating the area of the sample with one or more pulses of a laser, the laser configured to direct pulses at the sample surface;
   irradiating at least part of the area with an excitation beam of electrons or electromagnetic radiation;
   measuring intensities and energies of electrons emitted from the at least part of the area of the sample as a result of the excitation beam; and
   determining a chemical composition of the surface based on the measured intensities and energies of the emitted electrons,
   wherein the laser pulses and excitation beam are spatially coincident at the sample surface.
G43. An electron spectroscopy apparatus for determining a chemical composition of a sample, the apparatus comprising:
   a vacuum chamber;
   a sample stage mounted in the vacuum chamber, the sample stage configured for receiving a sample to be analysed;
   a laser configured to generate and direct laser pulses at a target area of the sample to ablate a surface of the sample;
   an excitation beam source configured to generate and direct an excitation beam of electrons or electromagnetic radiation at the target area of the sample; and
   an electron analyser and detector configured to measure energies and intensities of electrons emitted from the sample surface in response to the excitation beam and to determine a quantitative surface depth profile of the chemical composition of the sample.
G44. The apparatus of clause G43, wherein the electron analyser is further configured to determine, from the intensities and energies of the emitted electrons, the chemical state of the elements in the chemical composition.
G45. The apparatus of clause G43 or G44, wherein the laser is configured to generate pulses having a duration less than 1 ns, less than 1 ps, less than 500 fs, less than 100 fs, less than 10 fs or less than 1 fs.
G46. The apparatus of any of clauses G43 to G45, wherein the excitation beam source is configured to generate a beam of X-rays.
G47. The apparatus of any of clauses G43 to G45, wherein the excitation beam source is configured to generate a beam of X-rays and the electron analyser is configured to measure photoelectrons.
G48. The apparatus of any of clauses G43 to G47, wherein the sample stage is configured to be tilted with respect to the ablation laser beam.
G49. The method of any of clauses G43 to G48, wherein: (i) the sample stage is configured for rotating the sample in a plane of the surface of the sample and a controller is configured to control the sample stage to rotate between the steps of ablating and/or between the laser pulses, and/or the laser comprises a polarisation controller configured for (ii) rotating a plane of polarisation of the laser pulses between the steps of ablating and/or between the laser pulses or (iii) converting a polarisation of the laser pulses into circular or elliptical polarisation.
G50. The apparatus of any of clauses G43 to G49, wherein the sample stage comprises positioning devices to move the sample in orthogonal directions in the plane of the sample so as to raster scan the sample with respect to the position of incidence of the ablation laser pulses.
G51. The apparatus of any of clauses G43 to G50, wherein the laser comprises a mirror to adjust the position of incidence of the laser pulses on the sample so to raster scan the laser pulses across the sample.
G52. The apparatus of any of clauses G43 to G51, wherein the laser comprises a beam-shaping element to convert the laser-pulses to have a substantially flat-top or top-hat intensity profile across its diameter incident at the sample surface.
G53. The apparatus of clause G52, wherein the laser the beam-shaping element is configured to convert the laser pulses to have the substantially flat-top or top-hat intensity profile across its diameter incident at the sample surface and the diameter at the surface of the sample is greater than the diameter of the excitation beam at the surface of the sample.
G54. The apparatus of clause G52 or G53, wherein the beam-shaping element comprises a diffractive optical element or refractive optical element.
G55. The apparatus of any of clauses G43 to G54, wherein the laser is configured to generate pulses having an energy per in the range 10 nJ to 1000 μJ.
G56. The apparatus of any of clauses G43 to G55, wherein the laser is configured to generate pulses having a spot size at the sample surface in the range 1 to 1000 μm.
G57. The apparatus of any of clauses G43 to G56, further comprising a controller configured to adjust one or more parameters of the pulses of the laser based on composition information about a sample.
G58. The apparatus of any of clauses G43 to G57, wherein the one or more parameters of the laser pulses set by the controller comprise one or more of: pulse duration, pulse energy, repetition frequency, wavelength and spot size.
G59. The apparatus of any of clauses G43 to G58, wherein the controller is configured to:
   receive an input from a user indicating the composition information about the sample; and
   adjusting the one or laser parameters based on the composition information.
G60. The apparatus of any of clauses G43 to G59, wherein the controller is configured to refer to a reference database or algorithm to determine the laser parameters based on the information about the sample.
G61. The apparatus of any of clauses G43 to G60, wherein the laser and excitation beam source are respectively configured to direct the laser pulses and excitation beam to be spatially coincident at the sample surface.
H62. An electron spectroscopy apparatus, comprising:
   a vacuum chamber;
   a sample stage mounted in the vacuum chamber, the sample stage configured for receiving a sample to be analysed;
   a laser configured to generate and direct laser pulses at a target area of the sample to ablate a surface of the sample, wherein the laser is configured to ablate material to form a crater in the surface of the sample;
   an excitation beam source configured to generate and direct an excitation beam of electrons or electromagnetic radiation at the target area of the sample; and
   an electron analyser and detector configured to measure energies and intensities of electrons emitted from the sample surface in response to the excitation beam and to determine a surface depth profile of the chemical composition of the sample.
163. An electron spectroscopy apparatus, comprising:
   a vacuum chamber;
   a sample stage mounted in the vacuum chamber, the sample stage configured for receiving a sample to be analysed;
   a laser configured to generate and direct laser pulses at a target area of the sample to ablate a surface of the sample, wherein the laser is configured to generate pulses having a duration less than 1 ns, 1 ps, less than 500 fs, less than 100 fs, less than 10 fs or less than 1 fs;
   an excitation beam source configured to generate and direct an excitation beam of electrons or electromagnetic radiation at the target area of the sample; and
   an electron analyser and detector configured to measure energies and intensities of electrons emitted from the sample surface in response to the excitation beam and to determine a surface depth profile of the chemical composition of the sample.
J64. An electron spectroscopy apparatus, comprising:
   a vacuum chamber;
   a sample stage mounted in the vacuum chamber, the sample stage configured for receiving a sample to be analysed;
   a laser configured to generate and direct laser pulses at a target area of the sample to ablate a surface of the sample;
   a controller configured to adjust or set one or more parameters of pulses of the laser based on information about the sample;
   an excitation beam source configured to generate and direct an excitation beam of electrons or electromagnetic radiation at the target area of the sample; and
   an electron analyser and detector configured to measure energies and intensities of electrons emitted from the sample surface in response to the excitation beam and to determine a surface depth profile of the chemical composition of the sample.
K65. An electron spectroscopy apparatus, comprising:
   a vacuum chamber;
   a sample stage mounted in the vacuum chamber, the sample stage configured for receiving a sample to be analysed;
   a laser configured to generate and direct laser pulses at a target area of the sample to ablate a surface of the sample;
   an excitation beam source configured to generate and direct an excitation beam of electrons or electromagnetic radiation at the target area of the sample; and
   an electron analyser and detector configured to measure energies of electrons and intensities emitted from the sample surface in response to the excitation beam and to determine a surface depth profile of the chemical composition of the sample,
   wherein the sample stage is configured for a maximum amount of movement corresponding the to the size of the sample.
L66. An electron spectroscopy apparatus, comprising:
   a vacuum chamber;
   a sample stage mounted in the vacuum chamber, the sample stage configured for receiving a sample to be analysed;
   a laser configured to generate and direct laser pulses at a target area of the sample to ablate a surface of the sample;
   an excitation beam source configured to generate and direct an excitation beam of electrons or electromagnetic radiation at the target area of the sample; and
   an electron analyser and detector configured to measure energies and intensities of electrons emitted from the sample surface in response to the excitation beam and to determine a surface depth profile of the chemical composition of the sample,
   wherein the laser and excitation beam source are respectively configured to direct the laser pulses and excitation beam to be spatially coincident at the sample surface.

1. A method of determining a chemical composition of a sample using electron spectroscopy, the method comprising:
ablating material from an area on a surface of a sample by irradiating the area with one or more pulses of a laser;
irradiating at least part of the area with an excitation beam of electrons or electromagnetic radiation;
measuring intensities and energies of electrons emitted from the at least part of the area of the sample as a result of the excitation beam; and
repeating the steps of: ablating material, irradiating with the excitation beam, and measuring intensities and energies, to determine a quantitative surface depth profile of the chemical composition of at least part of the sample.

2-3. (canceled)

4. The method of claim 1, further comprising determining a depth or relative depth of the ablated area er areas.

5. The method of claim 1, wherein the one or more pulses of the laser each have a duration less than 1 ps.

6-12. (canceled)

13. The method of claim 1, wherein the step of ablating material forms a crater in the surface of the sample, and wherein the at least part of the area irradiated with the excitation beam of electrons comprises an area at the bottom of the crater.

14-16. (canceled)

17. The method of claim 13, wherein the step of ablating material from an area of the sample comprises moving the relative position of the pulses of the laser to scan the pulses of the laser over the area on the surface of the sample to ablate the crater in the surface.

18. (canceled)

19. The method of claim 17, wherein the scanning comprises irradiating the sample with one or more pulses of the laser at a plurality of partially overlapping pixel positions.

20-26. (canceled)

27. The method of claim 1, further comprising:
setting, by a controller, one or more parameters of the pulses of the laser based on composition information about a sample;
performing the step of ablating material, wherein the parameters of the pulses of the laser are set by the controller; and
following steps of ablating material, irradiating with the excitation beam and measuring electron intensities and energies:
adjusting the one or more parameters of the pulses of the laser based on measured or predicted composition information about the sample at a depth following the ablation; and
repeating the steps of ablating material, irradiating with the excitation beam and measuring electron intensities and energies using the adjusted one or more parameters of the pulses of the laser.

28-34. (canceled)

35. The method of claim 1, further comprising placing the sample on a sample stage in a vacuum chamber and following the steps of ablating material, irradiating with the excitation beam, and measuring intensities and energies of emitted electrons,
wherein the sample is not moved by an amount greater than the size of the sample between the step of ablating and the step of irradiating with the excitation beam.

36. The method of claim 1, wherein the pulses of the laser and the excitation beam are spatially coincident at the sample surface.

37-39. (canceled)

40. A method of electron spectroscopy, comprising:
setting, by a controller, one or more parameters of pulses of a laser based on composition information about a sample;
ablating material from an area on a surface of the sample by irradiating the area of the sample with one or more pulses of the laser, wherein the parameters of the pulses of the laser have been set by the controller;
irradiating at least part of the area with an excitation beam of electrons or electromagnetic radiation;
measuring intensities and energies of electrons emitted from the at least part of the area of the sample as a result of the excitation beam;
adjusting the one or more parameters of the pulses of the laser based on measured or predicted composition information about the sample at a depth following the ablation;
repeating the steps of ablating material, irradiating with the excitation beam and measuring electron intensities and energies using the adjusted one or more parameters of the pulses of the laser; and
determining a chemical composition of the surface based on the measured intensities and energies of the emitted electrons.

41-42. (canceled)

43. An electron spectroscopy apparatus for determining a chemical composition of a sample, the apparatus comprising:
a vacuum chamber;
a sample stage mounted in the vacuum chamber, the sample stage configured for receiving a sample to be analysed;
a laser source configured to generate and direct laser pulses at a target area of the sample to ablate a surface of the sample;
an excitation beam source configured to generate and direct an excitation beam of electrons or electromagnetic radiation at the target area of the sample; and
an electron analyser and detector configured to measure energies and intensities of electrons emitted from the sample surface in response to the excitation beam and to determine a quantitative surface depth profile of the chemical composition of the sample.

44-48. (canceled)

49. The method of claim 40, wherein the one or more parameters of the pulses of the laser set by the controller comprise one or more of: pulse duration, pulse energy, repetition frequency, wavelength, or spot size.

50. The method of claim 40, wherein the step of setting further comprises:
receiving an input from a user indicating the composition information about the sample; and
the controller adjusting the one or parameters of the pulses of the laser based on the composition information.

51. The method of claim 40, further comprising:
performing a survey scan or survey profile to determine an approximate measure of elemental components in the sample; and
generating the one or more parameters of the pulses of the laser based on the approximate measure.

52. The method of claim 40, further comprising:
performing mechanical profilometry, microscopy or white light interferometry of the sample surface; and
generating or adjusting the one or more parameters of the pulses of the laser based on the profilometry, microscopy or white light interferometry.

53. The method of claim 40, further comprising the controller using a reference database or algorithm to determine the parameters of the pulses of the laser based on the information about the sample.

54. The method of claim 40, further comprising repeating the steps of adjusting, ablating material, irradiating with the excitation beam and measuring electron intensities and energies until the sample has been analysed to a target depth.

55. The electron spectroscopy apparatus of claim 43, wherein the laser source is configured to generate laser pulses having a duration less than 1 ps.

56. The electron spectroscopy apparatus of claim 43, wherein the sample stage is configured to be tilted with respect to a beam of the pulses of the laser.

57. The electron spectroscopy apparatus of claim 43, wherein the laser source and the excitation beam source are respectively configured to direct the pulses of the laser and the excitation beam to be spatially coincident at the surface of the sample.
